(19) United States
(12) Patent Application Publication
(10) Pub. No.: US 2026/0372106 A1
(43) Pub. Date: Nov. 19, 2026

(54) QUANTUM CHIP PACKAGE STRUCTURES HAVING MULTILEVEL WIRING WITH ELECTROMAGNETIC SHIELDING

(71) Applicant: International Business Machines Corporation, Armonk, NY (US)

(72) Inventors: David Abraham, Croton, NY (US); John Michael Cotte, New Fairfield, CT (US); Adinath Shantinath Narasgond, Yonkers, NY (US); So-Young Kim, White Plains, NY (US); Jae-Woong Nah, Closter, NJ (US)

(21) Appl. No.: 18/659,308

(22) Filed: May 9, 2024

(51) Int. Cl. H10W 42/20; G06N 10/40; H10N 69/00; H10W 80/00; H10W 90/00; H10W 90/20

(52) U.S. Cl. CPC H10W 42/271; H10N 69/00; H10W 42/267; H10W 80/312; H10W 80/314; H10W 90/297; H10W 90/792; G06N 10/40

(57) ABSTRACT

A package structure comprises superconducting quantum circuit components disposed on a first surface of a first dielectric substrate, and a multilevel wiring structure disposed on a second surface of the first dielectric substrate, opposite the first surface. The multilevel wiring structure comprises wiring to provide connections between at least some of the superconducting quantum circuit components, and an integrated electromagnetic shielding structure. The integrated electromagnetic shielding structure is configured to shield the wiring of the multilevel wiring structure from electromagnetic interference and to shield the superconducting quantum circuit components from the wiring of the multilevel wiring structure.

### BACKGROUND

This disclosure relates generally to superconducting quantum devices for quantum computing and, in particular, to quantum chip package structures and techniques for packaging quantum chips with backside multilevel wiring structures. A quantum computing system can be implemented using superconducting circuit quantum electrodynamics (cQED) architectures that are constructed using quantum circuit components such as, e.g., superconducting quantum bits and other types of superconducting quantum devices that are controlled using microwave and/or flux bias control signals. In general, superconducting quantum bits (qubits) are electronic circuits which are implemented using components such as superconducting tunnel junctions (e.g., Josephson junctions), superconducting quantum interference devices (SQUIDs), inductors, and/or capacitors, etc., and which behave as quantum mechanical anharmonic (non-linear) oscillators with quantized states, when cooled to cryogenic temperatures.

Various types of quantum information processing algorithms can be implemented using a superconducting quantum processor which comprises multiple superconducting qubits that are coupled together in a qubit lattice, wherein the superconducting qubits can be coherently controlled, placed into quantum superposition states, exhibit quantum interference effects, and become entangled with one another, by applying various types of quantum gate operations (e.g., single-qubit gate operations, two-qubit gate operations, etc.) to the superconducting qubits. As quantum processors are scaled with increasing numbers of superconducting qubits with higher integration and connection densities, a primary challenge is being able to scale the number of qubits and qubit connectivity to meet signal routing and circuit density requirements, without introducing additional channels of noise and unwanted exchange interactions that result in correlated gate errors.

### SUMMARY

Exemplary embodiments of the disclosure include quantum chip package structures which comprise low-loss multilevel wiring structures with integrated electromagnetic shielding, and techniques for fabricating such quantum chip package structures.

For example, an exemplary embodiment includes a package structure which comprises superconducting quantum circuit components disposed on a first surface of a first dielectric substrate, and a multilevel wiring structure disposed on a second surface of the first dielectric substrate, opposite the first surface. The multilevel wiring structure comprises wiring to provide connections between at least some of the superconducting quantum circuit components, and an integrated electromagnetic shielding structure. The integrated electromagnetic shielding structure is configured to shield the wiring of the multilevel wiring structure from electromagnetic interference and to shield the superconducting quantum circuit components from the wiring of the multilevel wiring structure.

Advantageously, the integration of an electromagnetic shielding structure in a multilevel wiring structure enables high integration density of wiring (e.g., quantum bit coupling buses) to provide backside connections between superconducting quantum circuit components (e.g., quantum bits) of, e.g., a quantum chip. The integrated electromagnetic shielding structure of the multilevel wiring structure provides isolation between wiring on different wiring levels of the multilevel wiring structure (e.g., to prevent crosstalk between the wiring on different wiring levels), as well as isolation between the wiring and the superconducting quantum circuit components on the quantum chip. Moreover, the integrated electromagnetic shielding structure provides isolation and electromagnetic shielding of the wiring of the multilevel wiring structure from external sources of electromagnetic interference (EMI).

Another exemplary embodiment includes a package structure which comprises superconducting quantum circuit components disposed on a first surface of a first dielectric substrate, and a multilevel wiring structure disposed on second surface of the first dielectric substrate, opposite the first surface. The multilevel wiring structure comprises a first layer, a second layer, and an integrated electromagnetic shielding structure. The first layer and the second layer comprise wiring that is routed through the multilevel wiring structure to provide connections between at least some of the superconducting quantum circuit components. The integrated electromagnetic shielding structure is configured to shield the wiring of the multilevel wiring structure from electromagnetic interference, to shield the superconducting quantum circuit components from the wiring of the multilevel wiring structure, and to shield wiring of the first layer from wiring of the second layer.

In another exemplary embodiment, as may be combined with the preceding paragraphs, the superconducting quantum circuit components comprise a first quantum bit and a second quantum bit, and the wiring of the multilevel wiring structure comprises at least one coupling bus which is routed through the multilevel wiring structure to couple the first quantum bit and the second quantum bit.

In another exemplary embodiment, as may be combined with the preceding paragraphs, the integrated electromagnetic shielding structure comprises a first ground shield, a second ground shield, and a plurality of ground vias which are coupled to and between the first ground shield and the second ground shield, and which are arranged to form a via fence between the first and second ground shield. The wiring of the multilevel wiring structure is disposed between the first ground shield and the second ground shield, and surrounded by the via fence. The first ground shield is disposed between the wiring and the superconducting quantum circuit components on the first surface of the first dielectric substrate.

Another exemplary embodiment includes a package structure which comprises a first dielectric substrate, a second dielectric substrate, a third dielectric substrate, and an integrated electromagnetic shield structure. The first dielectric substrate comprises superconducting quantum circuit components disposed on a first surface of the first dielectric substrate, and a first metallization layer disposed on a second surface of the first dielectric substrate and comprising a first ground plane. The second dielectric substrate comprises a second metallization layer and a third metallization layer. The second metallization layer is disposed on a first surface of the second dielectric substrate and comprises a second ground plane that is bonded to the first ground plane. The third metallization layer is disposed on a second surface of the second dielectric substrate, and comprises a third ground plane and wiring to provide connections between at least some of the superconducting quantum circuit components. The third dielectric substrate comprises a fourth metallization layer and a fifth metallization layer. The fourth metallization layer is disposed on a first surface of the third dielectric substrate, and comprises a fourth ground plane which is bonded to the third ground plane. The fifth metallization layer is disposed on a second surface of the third dielectric substrate and comprises a fifth ground plane. The electromagnetic shielding structure is configured to shield the wiring of the third metallization layer from the superconducting quantum circuit components. The electromagnetic shielding structure comprises a first ground shield which comprises the bonded first and second ground planes, and a second ground shield which comprises the fifth ground plane.

Another exemplary embodiment includes a package structure which comprises a quantum chip, and a multilevel wiring structure. The quantum chip comprises a dielectric substrate, a plurality of superconducting quantum bits and quantum circuit components disposed on a frontside of the dielectric substrate, and a ground plane disposed on a backside of the dielectric substrate. The multilevel wiring structure is disposed on the backside of the dielectric substrate of the quantum chip and comprises at least one coupling bus which is routed through the multilevel wiring structure and the dielectric substrate of the quantum chip to couple a first superconducting quantum bit and a second superconducting quantum bit of the plurality of superconducting quantum bits. The multilevel wiring structure comprises a plurality of layers and an integrated electromagnetic shielding structure. Each layer of the plurality of layers comprises a dielectric substrate formed of a monocrystalline dielectric material, metallization layers disposed on first and second surfaces of the dielectric substrate, and through-substrate vias disposed in the dielectric substrate. The integrated electromagnetic shielding structure comprises patterned features of the metallization layers and at least a portion of the through-substrate vias of one or more layers of the plurality of layers. The integrated electromagnetic shielding structure is configured to shield the at least one coupling bus in the multilevel wiring structure from electromagnetic interference, and to shield the superconducting quantum bits and the quantum circuit components from the at least one coupling bus in the multilevel wiring structure.

Another exemplary embodiment includes a method for fabricating a package structure. First vias and a first metallization layer are formed on a first side of a first dielectric substrate comprising a monocrystalline dielectric material. Second vias and a second metallization layer are formed on a first side of a second dielectric substrate comprising a monocrystalline dielectric material. The first dielectric substrate and the second dielectric substrate are bonded by metal-to-metal bonding the first metallization layer and the second metallization layer. A thinned second dielectric substrate is formed by thinning down a second side of the second dielectric substrate to reveal the second vias. A third metallization layer is formed on the thinned second dielectric substrate in contact with the revealed second vias, wherein the third metallization layer comprises a ground plane and at least one planar wire. A thinned first dielectric substrate is formed by thinning down a second side of the first dielectric substrate to reveal the first vias. A fourth metallization layer and a plurality of superconducting quantum bits are formed on the thinned first dielectric substrate, with the fourth metallization layer in contact with the revealed first vias.

Other embodiments will be described in the following detailed description of exemplary embodiments, which is to be read in conjunction with the accompanying figures.

### BRIEF DESCRIPTION OF THE DRAWINGS

FIGS. 1A, 1B, and 1C are schematic views of a quantum chip package structure which comprises a low-loss multilevel wiring structure with integrated electromagnetic shielding, according to an exemplary embodiment of the disclosure.

FIGS. 2A and 2B are schematic cross-sectional views of a quantum chip package structure which comprises a low-loss multilevel wiring structure with integrated electromagnetic shielding, according to another exemplary embodiment of the disclosure.

FIGS. 3A and 3B are schematic cross-sectional views of a quantum chip package structure which comprises a low-loss multilevel wiring structure with integrated electromagnetic shielding, according to another exemplary embodiment of the disclosure.

FIGS. 4A through 4Q schematically illustrate a method for fabricating a quantum chip package structure which comprises a low-loss multilevel wiring structure with integrated electromagnetic shielding, according to an exemplary embodiment of the disclosure, wherein:

FIG. 4A schematically illustrates an intermediate stage of fabrication of the package structure in which a first wafer is processed to form a plurality of first vias in a first surface of the first wafer;

FIG. 4B schematically illustrates an intermediate stage of fabrication of the package structure after forming a metallization layer on the first surface of the first wafer in contact with the first vias;

FIG. 4C schematically illustrates an intermediate stage of fabrication of the package structure in which a second wafer is processed to form a plurality of second vias in a first surface of the second wafer;

FIG. 4D schematically illustrates an intermediate stage of fabrication of the package structure after forming a metallization layer on the first surface of the second wafer in contact with the second vias;

FIG. 4E schematically illustrates an intermediate stage of fabrication of the package structure after bonding the first wafer and the second wafer together using a metal-to-metal bonding process to bond the metallization layers of the first and second wafers;

FIG. 4F schematically illustrates an intermediate stage of fabrication of the package structure after performing a wafer thinning process to thin down the backside of the second wafer to reveal the second vias;

FIG. 4G schematically illustrates an intermediate stage of fabrication of the package structure after forming a metallization layer on a surface of the thinned second wafer in contact with the revealed second vias;

FIG. 4H schematically illustrates an intermediate stage of fabrication of the package structure in which a third wafer is processed by etching a cavity in a surface of the third wafer;

FIG. 4I schematically illustrates an intermediate stage of fabrication of the package structure after forming a conformal metallization layer on the surface of the third wafer to line the etched cavity with metal and thereby form a metallized cap structure;

FIG. 4J schematically illustrates an intermediate stage of fabrication of the package structure in which the third wafer is aligned and bonded to the thinned second wafer using a metal-to-metal bonding process;

FIG. 4K schematically illustrates an intermediate stage of fabrication of the package structure after performing a wafer thinning process to thin down a backside of the first wafer to reveal the first vias;

FIG. 4L schematically illustrates an intermediate stage of fabrication of the package structure after forming a metallization layer on a surface of the thinned first wafer in contact with the revealed first vias;

FIG. 4M schematically illustrates an intermediate stage of fabrication of an interposer wafer stack, in which an interposer wafer is processed to form a plurality of vias in a frontside surface of the interposer wafer;

FIG. 4N schematically illustrates an intermediate stage of fabrication of the interposer wafer stack after forming a multilevel wiring structure on the frontside surface of the interposer wafer;

FIG. 4O schematically illustrates an intermediate stage of fabrication of the interposer wafer stack after bonding support (handle) wafer to the multilevel wiring structure on the frontside of the interposer wafer;

FIG. 4P schematically illustrates an intermediate stage of fabrication of the interposer wafer stack after performing a wafer thinning process to thin down the backside of the interposer wafer to reveal the vias in the interposer wafer; and

FIG. 4Q schematically illustrates an intermediate stage of fabrication of the interposer wafer stack after forming a metallization layer on a surface of the thinned interposer wafer in contact with the revealed vias, and after forming the solder bumps on bump pads of the metallization layer.

FIGS. 5A through 5D schematically illustrate a method for fabricating a quantum chip package structure which comprises a low-loss multilevel wiring structure with integrated electromagnetic shielding, according to another exemplary embodiment of the disclosure, wherein:

FIG. 5A schematically illustrates an intermediate stage of fabrication of the package structure after forming the exemplary stack structure shown in FIG. 4G and after bonding a third wafer to the thinned second wafer of the stack structure using a metal-to-metal bonding process;

FIG. 5B schematically illustrates an intermediate stage of fabrication of the package structure after performing a wafer thinning process to thin down a backside of the third wafer to reveal the third vias, and after forming a metallization layer on the backside surface of the thinned third wafer in contact with the revealed third vias;

FIG. 5C schematically illustrates an intermediate stage of fabrication of the package structure after bonding a support (handle) wafer to the thinned third wafer; and

FIG. 5D schematically illustrates an intermediate stage of fabrication of the package structure after performing a wafer thinning process to thin down the backside of the first wafer to reveal the first vias, and after forming a metallization layer on the backside surface of the thinned first wafer in contact with the revealed first vias.

FIGS. 6A through 6C schematically illustrate a method for fabricating a quantum chip package structure which comprises a low-loss multilevel wiring structure with integrated electromagnetic shielding, according to another exemplary embodiment of the disclosure, wherein:

FIG. 6A is a schematic cross-sectional view of a wafer stack at an intermediate stage of fabrication after thinning down a first wafer to reveal ground vias and form a thinned dielectric substrate of a quantum chip;

FIG. 6B is a schematic cross-sectional view of the wafer stack at an intermediate stage of fabrication after forming a plurality of via holes which extend through dielectric substrates of multiple layers of the wafer stack to expose end portions of horizontal wires of qubit couplers in metallization layers of the wafer stack; and

FIG. 6C is a schematic cross-sectional view of the wafer stack at an intermediate stage of fabrication after filling the via holes with a superconducting metal to form continuous through-substrate vias which extend through multiple dielectric substrates of the wafer stack to form vertical wires of the qubit couplers.

FIG. 7 illustrates a flow diagram of a method for a method for fabricating a quantum chip package structure which comprises a low-loss multilevel wiring structure with integrated electromagnetic shielding, according to another exemplary embodiment of the disclosure.

FIG. 8 is a schematic cross-sectional view of a quantum chip package structure which comprises a low-loss multilevel wiring structure with integrated electromagnetic shielding, according to another exemplary embodiment of the disclosure.

FIG. 9 is a schematic cross-sectional view of a quantum chip package structure which comprises a low-loss multilevel wiring structure with integrated electromagnetic shielding, according to another exemplary embodiment of the disclosure.

FIG. 10 is a schematic cross-sectional view of a quantum chip package structure which comprises a low-loss multilevel wiring structure with integrated electromagnetic shielding, according to another exemplary embodiment of the disclosure.

FIG. 11 schematically illustrates a quantum computing system which comprises a quantum processor comprising a quantum chip package structure which comprises a low-loss multilevel wiring structure with integrated electromagnetic shielding, according to an exemplary embodiment of the disclosure.

### DETAILED DESCRIPTION

Exemplary embodiments of the disclosure will now be described in further detail with regard to quantum chip package structures which comprise low-loss multilevel wiring structures with integrated electromagnetic shielding, and techniques for fabricating such quantum chip package structures. In general, an exemplary embodiment of a quantum chip package structure comprises a quantum chip and a multilevel wiring structure, wherein the quantum chip comprises superconducting quantum circuit components (e.g., superconducting qubits) disposed on a frontside of the quantum chip. The multilevel wiring structure is disposed on a backside of the quantum chip and comprises one or more layers which comprise superconducting wiring to provide connections (e.g., qubit coupling buses) between at least some of the superconducting quantum circuit components disposed on the frontside of the quantum chip. In addition, the multilevel wiring structure comprises components (e.g., ground shields, grounded via fences, etc.) that collectively implement an integrated electromagnetic shielding structure which is configured to shield the wiring of the multilevel wiring structure from electromagnetic interference and to shield the superconducting quantum circuit components from the wiring of the multilevel wiring structure.

Moreover, as explained in further detail below, a backside multilevel wiring structure comprises one or more layers (e.g., wiring layers) which comprise low-loss monocrystalline dielectric substrates (e.g., interlayer dielectric layers). The low-loss monocrystalline dielectric substrates are fabricated from wafers, which are comprised of low-loss monocrystalline dielectric material (e.g., monocrystalline silicon), using wafer bonding and wafer thinning techniques, to thereby form a stack of low-loss wiring layers with wiring formed of superconducting metal material. The exemplary low-loss multilevel wiring structures and associated low-loss multilevel wiring fabrication methods provide advantages over conventional multilevel wiring structures which have inherently lossy amorphous interlayer dielectrics that are formed by depositing layers of dielectric material to form interlayer dielectric layers using deposition techniques such as CVD or plasma-enhanced (PE) CVD techniques, which limits the use of such multilevel wiring structures for quantum chip packages.

In addition, the integrated electromagnetic shielding structure is configured to provide a well-defined RF/microwave environment which essentially “encapsulates” the wiring of the backside multilevel wiring structure (from an RF/microwave perspective) in a well-defined environment that provides shielding and isolation of the backside wiring from the superconducting quantum circuit components (e.g., superconducting qubits) disposed on the frontside of the quantum chip, as well as from external sources of electromagnetic interference (EMI). In addition, the integrated electromagnetic shielding structure is configured to provide shielding between wiring (e.g., qubit coupling buses) in different layers of the backside multilevel wiring structure, thereby eliminating or significantly suppressing crosstalk between wiring on different wiring layers.

In some embodiments, the low-loss backside multilevel wiring structure is fabricated to have a network of low-loss qubit coupling buses which are routed through the backside multilevel wiring structure to connect superconducting qubits on the frontside of the quantum chip. In this regard, the ability to implement low-loss qubit coupling buses with high integration density in a quantum chip package, to couple superconducting qubits in a qubit lattice, is particularly advantageous for implementing topological quantum codes to realize fault-tolerant quantum computing architectures. As is known in the art, topological quantum codes are configured to encode quantum information (in the form of logical qubits) using a plurality of physical qubits, wherein such encoded quantum information can be used to extract information about errors induced by the environment (e.g., determine an error syndrome) and to correct such errors without collapsing stored quantum state of the logical qubit.

In this regard, topological quantum codes can be realized using a lattice of qubits that are coupled to each other via coupling buses. As superconducting quantum computing structures evolve and scale as a result of, e.g., advantages of using high-weight codes for fault-tolerant quantum computing, an exemplary quantum chip package structure having a low-loss multilevel wiring structure with integrated EMI shielding enables high-integration of a large number of qubit coupling buses to be routed through multiple layers of the low-loss multilevel wiring structure to connect superconducting qubits in a qubit lattice formed on the frontside of the quantum chip, as well as provide for longer range coupling buses between qubits that are disposed relatively far from each other in the qubit lattice, while the integrated EMI shielding isolates and shields the qubit coupling buses from each other and from external sources of EMI.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. To provide spatial context to the different structural orientations of the semiconductor structures shown in the drawings, XYZ Cartesian coordinates are shown in the drawings. The terms “vertical” or “vertical direction” or “vertical height” as used herein denote a Z-direction of the Cartesian coordinates shown in the drawings, and the terms “horizontal,” “horizontal direction,” “lateral,” or “lateral direction” as used herein denote an X-direction and/or a Y-direction of the Cartesian coordinates shown in the drawings.

In addition, for ease of explanation, one or more layers, structures, and regions of a type commonly used to form superconducting quantum devices and circuitry may not be explicitly shown in a given drawing. This does not imply that any layers, structures, and regions not explicitly shown are omitted from the actual superconducting quantum devices and circuits. It is to be further understood that references herein to formation of one layer or structure “on” or “over” another layer or structure are intended to be broadly construed, and should not be interpreted as precluding the presence of one or more intervening layers or structures.

Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional superconducting quantum devices or quantum circuits. Rather, certain processing steps that are commonly used in forming superconducting quantum devices or quantum circuits, such as, for example, metal deposition, wet cleaning and annealing steps, are purposefully not described herein for economy of description.

Further, the term “exemplary” as used herein means “serving as an example, instance, or illustration.” Any embodiment or design described herein as “exemplary” is not to be construed as preferred or advantageous over other embodiments or designs. The terms “about” or “substantially” as used herein with regard to thicknesses, widths, percentages, ranges, etc., are meant to denote being close or approximate to, but not exactly. For example, the term “about” or “substantially” as used herein implies that a small margin of error is present, such as 1% or less than the stated amount.

Moreover, the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise quantum circuit elements (e.g., quantum bits, tunable couplers, etc.), discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

In addition, the term “quantum chip” as used herein refers to a die (e.g., semiconductor die) which comprises a superconducting electronic integrated circuit (or quantum circuit) comprising various superconducting components such as qubits, tunable couplers, ground planes, signal coplanar waveguides, and resonators, etc. A plurality of dies having the same and/or different configurations of superconducting electronic integrated circuits, can be fabricated on a wafer (e.g., semiconductor wafer), wherein the individual dies can be diced (cut) from the wafer using a die singulation process to provide singulated dies which can be packaged together with low-loss multilevel wiring structures as discussed herein to construct a quantum chip package structure, to construct a quantum processor, or to construct a modular quantum processor architecture with multiple quantum chip package structures packaged together on a given interposer. Moreover, as explained in further detail below, a “quantum chip” can be fabricated to have a superconducting quantum circuit with multiple superconducting qubits, together with an integrated low-low multilevel wiring structure having transmission lines (e.g., control lines, readout resonators, etc.) to transmit signals to and from the superconducting qubits, as well as coupling buses (e.g., transmission line resonators) to couple qubits together to facilitate, e.g., two-qubit gate operations.

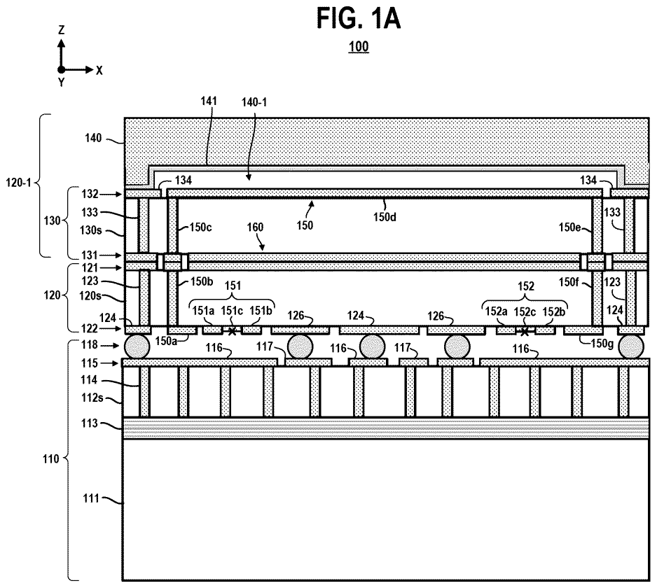

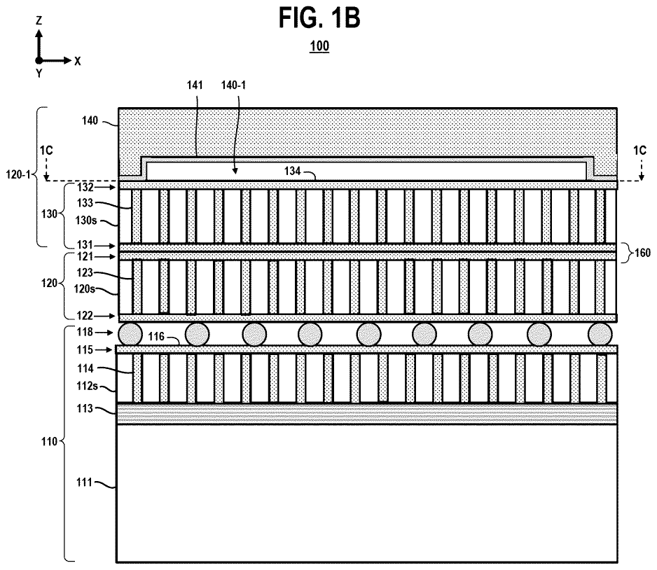

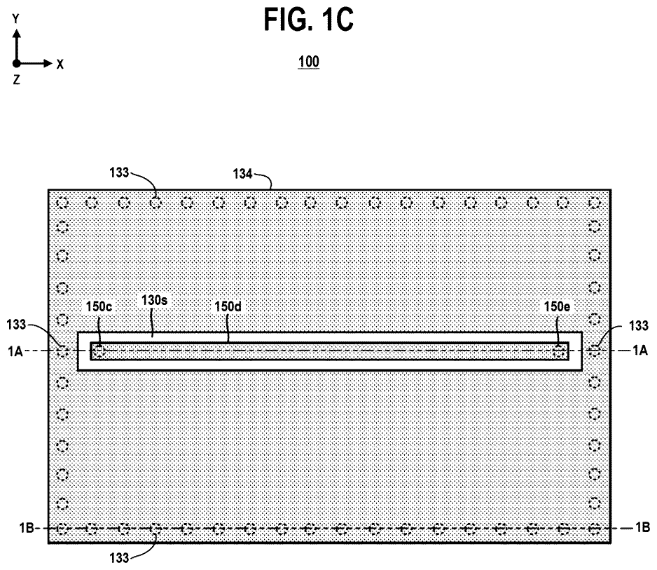

FIGS. 1A, 1B, and 1C are schematic views of a quantum chip package structure 100 which comprises a low-loss multilevel wiring structure with integrated electromagnetic shielding, according to an exemplary embodiment of the disclosure. In particular, FIGS. 1A and 1B are schematic cross-sectional views of the quantum chip package structure 100 along lines 1A-1A and 1B-1B, respectively, in FIG. 1C, while FIG. 1C is a schematic plan view of the quantum chip package structure 100 along line 1C-1C as shown in FIG. 1B. The quantum chip package structure 100 (or package structure 100) comprises an interposer 110, a quantum chip 120, and a backside multilevel wiring structure 120-1 disposed on a backside of the quantum chip 120. The backside multilevel wiring structure 120-1 comprises a first layer 130 (e.g., a first wiring layer) and a second layer comprising a cap structure 140. The package structure 100 further comprises a qubit coupling bus 150 (or qubit coupler 150), a plurality of superconducting qubits including a first superconducting qubit 151 and a second superconducting qubit 152 disposed on a frontside of the quantum chip 120, and a ground shield 160. As explained in further detail below, the ground shield 160 is configured to shield wiring in the backside multilevel wiring structure 120-1 from quantum devices (e.g., qubits) and quantum circuitry on the frontside of the quantum chip 120.

In some embodiments, as schematically shown in FIG. 1A, the qubit coupler 150 comprises a superconducting transmission line resonator which is routed through the quantum chip 120 and the backside multilevel wiring structure 120-1 of the package structure 100 to couple the first and second superconducting qubits 151 and 152. The qubit coupler 150 comprises a plurality of horizontal wire segments and vertical wire segments, e.g., wire segments 150a, 150b, 150c, 150d, 150e, 150f, and 150g. The wire segments 150a, 150d, and 150g comprise horizontal wire segments of the qubit coupler 150, which comprise patterned metal features of metallization layers, while the wire segments 150b, 150c, 150e, and 150f comprise vertical wire segments of the qubit coupler 150, which comprise through-substrate vias (TSVs) of the quantum chip 120 and the first layer 130 of the backside multilevel wiring structure 120-1.

The interposer 110 comprises a support substrate 111 (or handle substrate), a thinned dielectric substrate 112s, a multilevel wiring structure 113 formed on a first surface of the thinned dielectric substrate 112s, a plurality of TSVs 114 formed in the thinned dielectric substrate 112s, a metallization layer 115 formed on a second surface of the thinned dielectric substrate 112s, and a plurality of solder bumps 118 (e.g., indium solder bumps). The metallization layer 115 comprises a plurality of patterned metal features including, but not limited to, a ground plane 116, planar transmission lines 117, resonators, solder bump pads (e.g., under bump metallurgy (UBM)), etc. In some embodiments, the multilevel wiring structure 113 comprises a redistribution layer (RDL) that is configured to distribute input/output pads and connections through galvanic connections (e.g., solder bumps 118) and/or non-galvanic connections (e.g., capacitive couplings) with quantum devices and circuitry on the frontside of the quantum chip 120.

The quantum chip 120 comprises a thinned dielectric substrate 120s, a first metallization layer 121 formed on a first surface of the thinned dielectric substrate 120s, a second metallization layer 122 formed on a second surface of the thinned dielectric substrate 120s, and a plurality TSVs formed in the thinned dielectric substrate 120s, including ground TSVs 123 and signal TSVs (e.g., vertical wire segments 150b and 150f of the qubit coupler 150). The first metallization layer 121 comprises a ground plane which is a component of the ground shield 160. The second metallization layer 122 comprises a plurality of patterned metal features including, but not limited to, a ground plane 124, qubit readout resonators 126, as well as other patterned metal features such as, e.g., qubit capacitor pads of the first and second superconducting qubits 151 and 152, transmission lines, qubit control lines, horizonal wire segments of qubit coupling buses (e.g., horizontal wire segments 150a and 150g of the qubit coupler 150), solder bump pads (e.g., under bump metallurgy (UBM)), etc.

In an exemplary embodiment, the first superconducting qubit 151 comprises a superconducting transmon qubit which comprises a first superconducting capacitor pad 151a, a second superconducting capacitor pad 151b, and a Josephson junction 151c which is connected to and between the first and second superconducting capacitor pads 151a and 151b. Similarly, the second superconducting qubit 152 comprises a superconducting transmon qubit which comprises a first superconducting capacitor pad 152a, a second superconducting capacitor pad 152b, and a Josephson junction 152c which is connected to and between the first and second superconducting capacitor pads 152a and 152b. As is known in the art, a superconducting transmon qubit is a qubit which comprises a superconducting capacitor coupled in parallel with a Josephson junction. In FIG. 1A, the first and second superconducting capacitor pads 151a and 151b comprise first and second capacitor electrodes of a coplanar parallel plate capacitor of the first superconducting qubit 151, which is connected in parallel with the Josephson junction 151c of the first superconducting qubit 151. Similarly, the first and second superconducting capacitor pads 152a and 152b comprise first and second capacitor electrodes of a coplanar parallel plate capacitor, which is connected in parallel with the Josephson junction 152c of the second superconducting qubit 152.

While FIG. 1A illustrates two superconducting qubits for ease of illustration and explanation, it is to be understood that more than two superconducting qubits can be formed on the second (frontside) surface of the thinned dielectric substrate 120s, as well as other superconducting quantum devices and circuitry such as qubit control lines, readout resonators, etc. In addition, there can be coupled pairs of superconducting qubits that are formed in close proximity on the second surface of thinned dielectric substrate 120s and coupled via coupling buses that are formed on the second surface of the thinned dielectric substrate 120s. Moreover, while exemplary embodiments of the disclosure are discussed in the context of transmon qubits for illustrative purposes, the quantum chip 120 may comprise other types of superconducting qubits which comprise, e.g., one or more Josephson junctions and superconducting capacitors, such as fluxonium qubits, multimode qubits (e.g., two-junction qubits, or tunable coupling qubits), and other types of fixed-frequency qubits or tunable-frequency qubits which are suitable for a given application.

The first layer 130 (or first thinned chip with TSVs) comprises a thinned dielectric substrate 130s (e.g., interlayer dielectric layer), a first metallization layer 131 formed on a first surface of the thinned dielectric substrate 130s, a second metallization layer 132 formed on a second surface of the thinned dielectric substrate 130s, and a plurality of TSVs formed in the thinned dielectric substrate 130s, including ground TSVs 133 (which form a via fence), and signal TSVs (e.g., vertical wire segments 150c and 150e of the qubit coupler 150). The first metallization layer 131 comprises a ground plane which is a component of the ground shield 160. In an exemplary embodiment, as explained in further detail below, the quantum chip 120 and the first layer 130 are bonded together via, e.g., metal-to-metal bonding of the first metallization layers 121 and 131 (or portions thereof).

As schematically illustrated in FIGS. 1A, 1B, and 1C, the second metallization layer 132 comprises a plurality of patterned metal features including, but not limited to, a ground plane 134, and horizontal wiring of one or more qubit coupler buses (e.g., horizontal wire segment 150d of the qubit coupler 150). In some embodiments, as specifically shown in the plan view of FIG. 1C, the horizontal wire segment 150d and the ground plane 134 form a CPW transmission line. Moreover, the plurality ground TSVs 133 serve as ground vias that are disposed in the thinned dielectric substrate 130s. As schematically shown in FIG. 1C, a plurality of the ground TSVs 133 are arranged to form a “via fence” that surrounds an inner region of the thinned dielectric substrate 130s which comprises the horizontal wire segment 150d and vertical wire segments 150c and 150e of the qubit coupler 150.

The cap structure 140 comprises an inner cavity 140-1 (e.g., etched channel), and a metallization layer 141 which is coated on inner and bottom surfaces of cap structure 140. The metallization layer 141 of the cap structure 140 comprises an upper ground shield that is configured to provide electromagnetic shielding and isolation for the multilevel wiring structure 120-1. For example, the metallization layer 141 of the cap structure 140 provides an upper ground shield that is configured to electromagnetically shield the qubit coupler(s), which are routed in the first layer 130, from the outside environment. In some embodiments, the cap structure 140 further comprises a metallic gasket (thin layer of bonding metal) which is disposed on the portions of the metallization layer 141 on the bottom surfaces of the cap structure 140 to enable bonding of the cap structure 140 to the ground plane 134 of the second metallization layer 132 of the first layer 130. Moreover, in some embodiments, the second metallization layer 132 comprises a corresponding metallic bonding layer which is configured to bond with the metallic gasket of the cap structure 140 by metal-to-metal bonding.

It is to be appreciated that the exemplary package structure 100 is constructed using low-loss dielectric substrates which allows superconducting quantum devices and circuitry to be integrally packaged together with low-loss multilevel wiring layers. For example, in some embodiments, the thinned dielectric substrates 112s, 120s, and 130s of the package structure 100 are formed of low-loss monocrystalline (single crystal) dielectric material. In particular, in some embodiments, the thinned dielectric substrates 112s, 120s, and 130s are formed from semiconductor wafers comprising monocrystalline (single crystal) semiconductor material such as monocrystalline silicon. In other embodiments, the thinned dielectric substrates 112s, 120s, and 130s are formed from dielectric wafers comprising any suitable low-loss (high resistivity) dielectric material (e.g., resistivity of greater than 500 ohms-centimeter (Ω·cm)) such as single crystal aluminum oxide (Al₂O₃), single crystal magnesium oxide (MgO), single crystal silicon oxide (SiO₂), and other types of single crystal dielectric materials which are suitable for the given application. As explained in further detail below, the thinned dielectric substrates 112s, 120s, and 130s of the interposer 110, the quantum chip 120, and the first layer 130, respectively, are formed from wafers using wafer thinning techniques.

Moreover, the various metallization layers 115, 121, 122, 131, and 132 and TSVs of the interposer 110, the quantum chip 120, and the first layer 130 are formed of superconducting metal (or metallic material) which is suitable for the given application. For example, the superconducting metal (or metallic material) may be aluminum (Al), niobium (Nb), tantalum (Ta), titanium (Ti), tungsten (W), tin (Sn), molybdenum (Mo), or nitrides of the same, or combinations thereof, and/or the like. A superconducting metal or metallic material exhibits superconducting properties (e.g., no electrical resistance, expels magnetic fields when in a superconducting state) at or below a superconducting critical temperature.

It is to be appreciated that the exemplary package structure 100 comprises an integrated electromagnetic shielding structure which provides a well-defined microwave environment for the quantum devices, circuit components, and backend wiring of the package structure 100. For example, the cap structure 140, the via fence formed by the ground TSVs 133 of the first layer 130, and the ground shield 160, are collectively configured to provide an enclosed environment which isolates and shields the qubit coupler 150 (and other signal wiring) from electromagnetic interference in the external environment. More specifically, in the exemplary package configuration, the ground TSVs 133 (which form the via fence of the first layer 130) are configured to electrically couple the metallization layer 141 of the cap structure 140 to the ground shield 160, thereby essentially forming a Faraday cage which provides an enclosed and shielded microwave environment for the horizonal and vertical wire segments of qubit couplers (e.g., wire segments 150c, 150d, and 150e of qubit coupler 150) that are routed through the first layer 130.

Furthermore, it is to be appreciated that the ground shield 160, which is collectively formed by the first metallization layers 121 and 131 of the quantum chip 120 and the first layer 130, respectively, provides electromagnetic shielding of the first and second superconducting qubits 151 and 152 (and other quantum circuit components such as readout resonators on the frontside of the quantum chip 120) from the qubit coupler 150 (and other qubit couplers) in the first layer 130. In some embodiments, the ground shield 160 is essentially a large ground plane which has a footprint area which essentially covers the entire footprint areas of the quantum chip 120 and the first layer 130. However, as schematically illustrated in FIG. 1A, the ground shield 160 comprises open regions to allow the vertical wire segments (e.g., signal TSVs) of the qubit coupler 150 (and other couplers) to extend through the ground shield 160.

In other embodiments, the quantum chip 120 can be constructed to have an enclosed microwave environment by forming via fence comprises of a plurality of the ground TSVs 123 which surrounds an inner region of the thinned dielectric substrate 120s. In this instance, the via fence of ground TSVs 123 electrically couples the outer perimeter region of the ground shield 160 to the ground plane 124 on the frontside of the quantum chip 120. For example, FIG. 1B schematically illustrates an exemplary embodiment in which both the quantum chip 120 and the first layer 130 are formed with ground TSVs 123 and 133 that form respective via fences which surround the inner regions of the respective thinned dielectric substrates 120s and 130s.

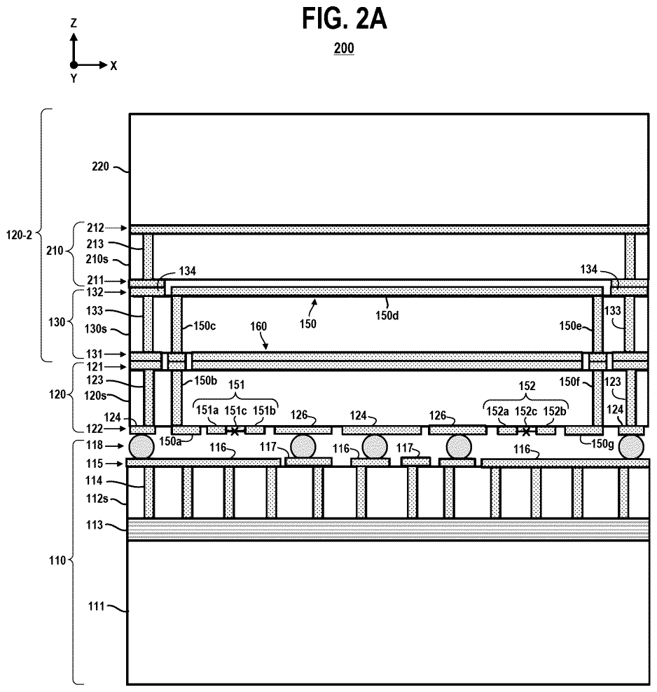

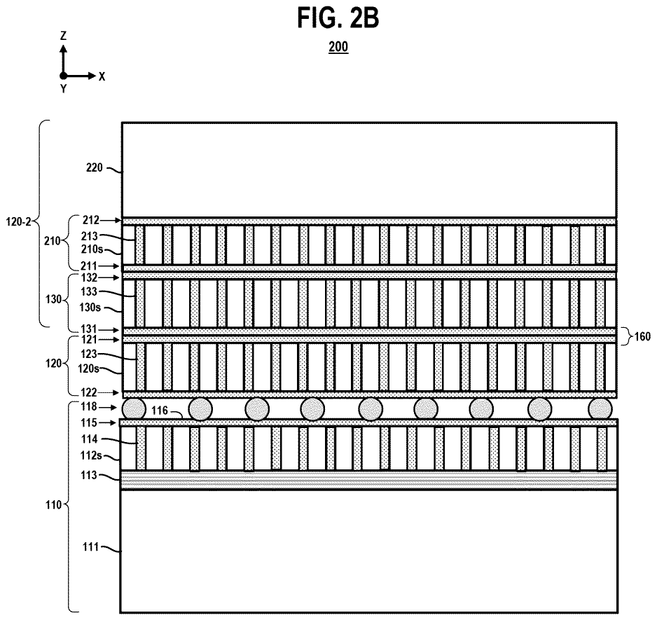

FIGS. 2A and 2B are schematic cross-sectional views of a quantum chip package structure 200 (or package structure 200) which comprises a low-loss multilevel wiring structure with integrated electromagnetic shielding, according to another exemplary embodiment of the disclosure. The exemplary quantum chip package structure 200 is similar to the quantum chip package structure 100 of FIGS. 1A-1C, except that the quantum chip package structure 200 comprises a backside multilevel wiring structure 120-2 which comprises an architecture which differs from the backside multilevel wiring structure 120-1 of the quantum chip package structure 100. In particular, the backside multilevel wiring structure 120-2 comprises the first layer 130 (as above), but further comprises a second layer 210 (e.g., upper EMI shielding layer) which is disposed on the first layer 130, and an optional support (handle) substrate 220 bonded to the second layer 210. In this exemplary embodiment, the second layer 210 is utilized in place of the cap structure 140 shown in FIGS. 1A-1C. It is to be noted that FIGS. 2A and 2B are schematic cross-sectional views of the quantum chip package structure 200, which correspond to the schematic cross-sectional views of the quantum chip package structure 100 shown in FIGS. 1A and 1B.

The second layer 210 (or second thinned chip with TSVs) comprises a thinned dielectric substrate 210s, a first metallization layer 211 formed on a first surface of the thinned dielectric substrate 210s, a second metallization layer 212 formed on a second surface of the thinned dielectric substrate 210s, and a plurality of ground TSVs 213 formed in the thinned dielectric substrate 210s. The first metallization layer 211 comprises a ground plane which has a footprint that is the same or similar to the ground plane 134 of the second metallization layer 132 of the first layer 130. In an exemplary embodiment, as explained in further detail below, the first layer 130 and the second layer 210 are bonded together via, e.g., metal-to-metal bonding of the ground planes of the respective metallization layers 132 and 211 (or portions thereof).

Moreover, the second metallization layer 212 of the second layer 210 serves as an upper ground shield that is configured to provide electromagnetic shielding and isolation for the backside multilevel wiring structure 120-2. For example, the second metallization layer 212 provides an upper ground shield that is configured to electromagnetically shield the qubit coupler(s), which are routed in the first layer 130, from the outside environment. The ground TSVs 213 are formed in the outer perimeter region of the thinned dielectric substrate 210s to form a via fence which electrically couples the second metallization layer 212 to the first metallization layer 211. Essentially, the second layer 210 is configured to provide isolation and electromagnetic shielding from the environment above the qubit coupler(s) that are routed through the first layer 130.

In this embodiment, the horizontal wire segment 150d of the qubit coupler 150 is disposed between the thinned dielectric substrates 130s and 210s with no gap (or a thin gap) between the horizontal wire segment 150d of the qubit coupler 150 and the thinned dielectric substrate 210s disposed over horizontal wire segment 150d. This configuration does not limit performance if the surface of the thinned dielectric substrate 210s is clean and does not contribute to loss. Further, the wiring of the qubit coupler 150 is designed by taking into account the increased dielectric constant of the material of the thinned dielectric substrate 210s above the horizontal wire segment 150d (as compared to the air gap resulting from the etched channel of the cap structure 140) to compensate and otherwise avoid impedance mismatch issues.

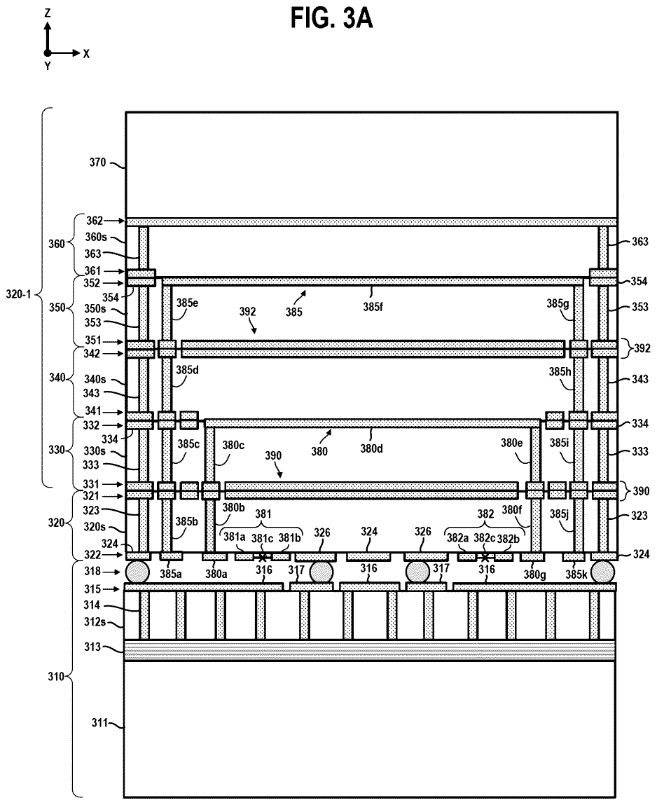

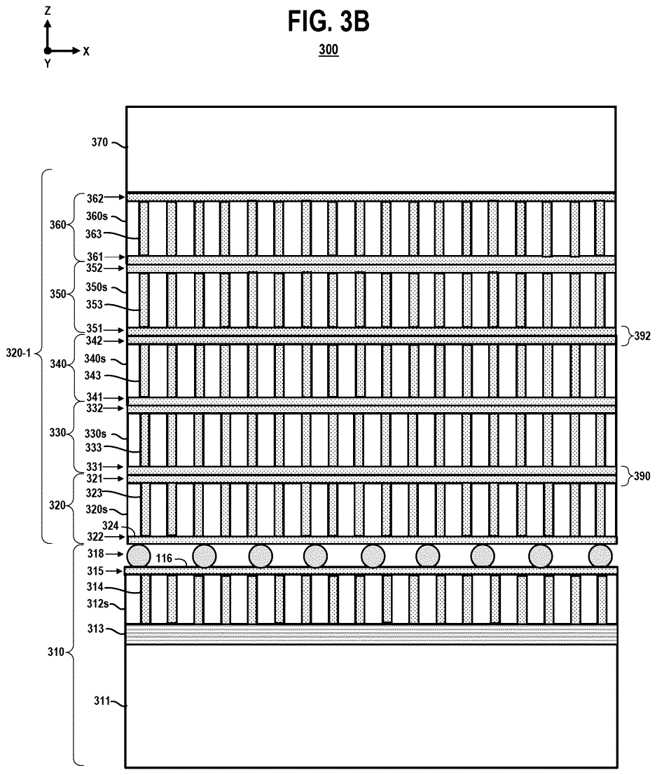

FIGS. 3A and 3B are schematic cross-sectional views of a quantum chip package structure 300 (or package structure 300) which comprises a low-loss multilevel wiring structure with integrated electromagnetic shielding, according to another exemplary embodiment of the disclosure. The quantum chip package structure 300 (or package structure 300) comprises an interposer 310, a quantum chip 320, and a backside multilevel wiring structure 320-1 disposed on a backside of the quantum chip 320. The backside multilevel wiring structure 320-1 comprises a first layer 330 (e.g., first wiring layer), a second layer 340 (e.g., second wiring layer), a third layer 350 (e.g., a third wiring layer), a fourth layer 360 (e.g., upper EMI shielding layer), and an optional support (handle) substrate 370. The backside multilevel wiring structure 320-1 of the quantum chip package structure 300 is similar in architecture to the backside multilevel wiring structure 120-2 of the package structure 200 of FIGS. 2A and 2B, except that the backside multilevel wiring structure 320-1 comprises additional layers (e.g., third and fourth layers 350 and 360) to provide additional levels of isolated and electromagnetically shielded qubit coupler wiring paths. It is to be noted that FIGS. 3A and 3B are schematic cross-sectional views of the quantum chip package structure 300, which correspond to the schematic cross-sectional views of the quantum chip package structures 100 and 200 shown in FIG. 1A/1B and 2A/2B.

As schematically shown in FIG. 3A, the package structure 300 further comprises a first qubit coupling bus 380 (or first qubit coupler 380), a second qubit coupling bus 385 (or second qubit coupler 385), a plurality of superconducting qubits including a first superconducting qubit 381 and a second superconducting qubit 382 disposed on a frontside of the quantum chip 320, a first ground shield 390, and a second ground shield 392. The first ground shield 390 is configured to shield wiring in the backside multilevel wiring structure 320-1 from quantum devices (e.g., qubits) and quantum circuitry on the frontside of the quantum chip 320, and the second ground shield 392 is configured to shield wiring in the third layer 350 from wiring in the first layer 330.

In some embodiments, as schematically shown in FIG. 3A, the first qubit coupler 380 comprises a superconducting transmission line resonator which is routed through the quantum chip 320 and the backside multilevel wiring structure 320-1 to couple the first and second superconducting qubits 381 and 382. The first qubit coupler 380 comprises a plurality of horizontal wire segments and vertical wire segments, e.g., wire segments 380a, 380b, 380c, 380d, 380e, 380f, and 380g. The wire segments 380a, 380d, and 380g comprise horizontal wire segments of the first qubit coupler 380, which comprise patterned metal features of metallization layers, while the wire segments 380b, 380c, 380e, and 380f comprise vertical wire segments of the first qubit coupler 380, which comprise TSVs of the quantum chip 320 and the first layer 330 of the backside multilevel wiring structure 320-1.

Similarly, the second qubit coupler 385 comprises a superconducting transmission line resonator which is routed through the quantum chip 320 and the backside multilevel wiring structure 320-1 to couple another pair of superconducting qubits (not specifically shown in FIG. 3A). The second qubit coupler 385 comprises a plurality of horizontal wire segments and vertical wire segments, e.g., wire segments 385a, 385b, 385c, 385d, 385e, 385f, 385g, 385h, 385i, 385j, and 385k. The wire segments 385a, 385f, and 385k comprise horizontal wire segments of the second qubit coupler 385, which comprise patterned metal features of metallization layers, while the wire segments 385b, 385c, 385d, 385e, 385g, 385h, 385i, and 385j comprise vertical wire segments of the second qubit coupler 385, which comprise TSVs of the quantum chip 320 and the first, second, and third layers 330, 340, and 350 of the backside multilevel wiring structure 320-1.

Similar to the exemplary package structures 100 and 200 discussed above, the interposer 310 comprises a support substrate 311 (or handle substrate), a thinned dielectric substrate 312s, a multilevel wiring structure 313 formed on a first surface of the thinned dielectric substrate 312s, a plurality of TSVs 314 formed in the thinned dielectric substrate 312s, a metallization layer 315 formed on a second surface of the thinned dielectric substrate 312s, and a plurality of solder bumps 318 (e.g., indium solder bumps). The metallization layer 315 comprises a plurality of patterned metal features including, but not limited to, a ground plane 316, planar transmission lines 317, resonators, solder bump pads (e.g., under bump metallurgy (UBM)), etc. In some embodiments, the multilevel wiring structure 313 comprises an RDL structure that is configured to distribute input/output pads and connections through galvanic connections (e.g., solder bumps 318) and/or non-galvanic connections (e.g., capacitive couplings) with quantum devices and circuitry on the frontside of the quantum chip 320.

The quantum chip 320 comprises a thinned dielectric substrate 320s, a first metallization layer 321 formed on a first surface of the thinned dielectric substrate 320s, a second metallization layer 322 formed on a second surface of the thinned dielectric substrate 320s, and a plurality TSVs formed in the thinned dielectric substrate 320s, including ground TSVs 323 and signal TSVs (e.g., respective vertical wire segments 380b, 380f, 385b, and 385j of the first and second qubit couplers 380 and 385). The first metallization layer 321 comprises a ground plane which is a component of the first ground shield 390. The second metallization layer 322 comprises a plurality of patterned metal features including, but not limited to, a ground plane 324, qubit readout resonators 326, as well as other patterned metal features such as, e.g., qubit capacitor pads of the first and second superconducting qubits 381 and 382, transmission lines, qubit control lines, horizonal wire segments of qubit coupling buses (e.g., respective horizontal wire segments 380a, 380g, 385a, and 385k of the first and second qubit couplers 380 and 385), solder bump pads (e.g., UBM pads), etc.

In an exemplary embodiment, the first superconducting qubit 381 comprises a superconducting transmon qubit which comprises a first superconducting capacitor pad 381a, a second superconducting capacitor pad 381b, and a Josephson junction 381c which is connected to and between the first and second superconducting capacitor pads 381a and 381b. Similarly, the second superconducting qubit 382 comprises a superconducting transmon qubit which comprises a first superconducting capacitor pad 382a, a second superconducting capacitor pad 382b, and a Josephson junction 382c, wherein the first and second superconducting capacitor pads 381a and 381b comprise first and second capacitor electrodes of a coplanar parallel plate capacitor of the first superconducting qubit 381, which is connected in parallel with the Josephson junction 381c of the first superconducting qubit 381. Similarly, the first and second superconducting capacitor pads 382a and 382b comprise first and second capacitor electrodes of a coplanar parallel plate capacitor of the second superconducting qubit 382, which is connected in parallel with the Josephson junction 382c of the second superconducting qubit 382.

The first layer 330 (or first thinned chip with TSVs) comprises a thinned dielectric substrate 330s, a first metallization layer 331 formed on a first surface of the thinned dielectric substrate 330s, a second metallization layer 332 formed on a second surface of the thinned dielectric substrate 330s, and a plurality of TSVs formed in the thinned dielectric substrate 330s, including ground TSVs 333 (which form a via fence), and signal TSVs (e.g., respective vertical wire segments 380c, 380e, 385c, and 385i of the first and second qubit couplers 380 and 385). The first metallization layer 331 comprises a ground plane which is a component of the first ground shield 390. In an exemplary embodiment, as explained in further detail below, the quantum chip 320 and the first layer 330 are bonded together via, e.g., metal-to-metal bonding of the first metallization layers 321 and 331 (or portions thereof).

The second metallization layer 332 of the first layer 330 comprises a plurality of patterned metal features including, but not limited to, a ground plane 334, and horizontal wiring of one or more qubit coupler buses (e.g., horizontal wire segment 380d of the first qubit coupler 380). In some embodiments, the horizontal wire segment 380d and the ground plane 334 form a CPW transmission line. Moreover, the ground TSVs 333 in the thinned dielectric substrate 330s are configured to electrically couple the ground plane 334 to the first ground shield 390. In some embodiments, a plurality of the ground TSVs 333 are arranged to form a “via fence” that surrounds an inner region of the thinned dielectric substrate 330s which comprises the horizontal wire segment 380d of the first qubit coupler 380, and the respective vertical wire segments 380c, 380e, 385c, and 385i of the first and second qubit couplers 380 and 385.

The second layer 340 (or second thinned chip with TSVs) comprises a thinned dielectric substrate 340s (e.g., second interlayer dielectric layer), a first metallization layer 341 formed on a first surface of the thinned dielectric substrate 340s, a second metallization layer 342 formed on a second surface of the thinned dielectric substrate 340s, and a plurality of TSVs formed in the thinned dielectric substrate 340s, including ground TSVs 343 (which form a via fence), and signal TSVs (e.g., vertical wire segments 385d, and 385h of the second qubit coupler 385). The first metallization layer 341 comprises a patterned ground plane. In an exemplary embodiment, as explained in further detail below, the first layer 330 and the second layer 340 are bonded together via, e.g., metal-to-metal bonding of the first metallization layer 341 (of the second layer 340) and the ground plane 334 of the second metallization layer 332 (of the first layer 330). The second metallization layer 342 comprises a ground plane which is a component of the second ground shield 392.

The third layer 350 (or third thinned chip with TSVs) comprises a thinned dielectric substrate 350s, a first metallization layer 351 formed on a first surface of the thinned dielectric substrate 350s, a second metallization layer 352 formed on a second surface of the thinned dielectric substrate 350s, and a plurality of TSVs formed in the thinned dielectric substrate 350s, including ground TSVs 353 (which form a via fence), and signal TSVs (e.g., vertical wire segments 385e, and 385g of the second qubit coupler 385). The first metallization layer 351 comprises a ground plane which is a component of the second ground shield 392. In an exemplary embodiment, as explained in further detail below, the second layer 340 and the third layer 350 are bonded together via, e.g., metal-to-metal bonding of the respective metallization layers 342 and 351, thereby forming the second ground shield 392.

The second metallization layer 352 of the third layer 350 comprises a plurality of patterned metal features including, but not limited to, a ground plane 354, and horizontal wiring of one or more qubit coupler buses (e.g., horizontal wire segment 385f of the second qubit coupler 385). In some embodiments, the horizontal wire segment 385f and the ground plane 354 form a CPW transmission line (e.g., similar to that shown in FIG. 1C). Moreover, the ground TSVs 353 in the thinned dielectric substrate 350s are configured to electrically couple the ground plane 354 to the second ground shield 392. In some embodiments, a plurality of the ground TSVs 353 are arranged to form a “via fence” that surrounds an inner region of the thinned dielectric substrate 350s which comprises the horizontal wire segment 385f and vertical wire segments 385e and 385g of the second qubit coupler 385.

The fourth layer 360 (or fourth thinned chip with TSVs) serves as an upper shielding layer of the backside multilevel wiring structure 320-1 (similar to the second layer 210 of the backside multilevel wiring structure 120-2 of the package structure 200 shown in FIGS. 2A and 2B). In particular, the fourth layer 360 comprises a thinned dielectric substrate 360s, a first metallization layer 361 formed on a first surface of the thinned dielectric substrate 360s, a second metallization layer 362 formed on a second surface of the thinned dielectric substrate 360s, and a plurality of ground TSVs 363 formed in the thinned dielectric substrate 360s. The first metallization layer 361 comprises a patterned ground plane which has a footprint that is the same or similar to the ground plane 354 of the second metallization layer 352 of the third layer 350. In an exemplary embodiment, as explained in further detail below, the third layer 350 and the fourth layer 360 are bonded together via, e.g., metal-to-metal bonding of the ground planes of the respective metallization layers 352 and 361 (or portions thereof).

Moreover, the second metallization layer 362 of the fourth layer 360 serves as an upper ground shield that is configured to provide electromagnetic shielding and isolation for the backside multilevel wiring structure 320-1. For example, the second metallization layer 362 provides an upper ground shield that is configured to electromagnetically shield the qubit coupler(s), which are routed in the third layer 350, from the outside environment. The ground TSVs 363 are formed in the outer perimeter region of the thinned dielectric substrate 360s to form a via fence which electrically couples the second metallization layer 362 to the first metallization layer 361. Essentially, the fourth layer 360 is configured to provide isolation and electromagnetic shielding from the environment above the qubit coupler(s) (e.g., second qubit coupler 385) of the backside multilevel wiring structure 320-1. In an alternate embodiment of the package structure 300, the fourth layer 360 (and the optional support substrate 370) can be replaced with a cap structure (which is similar to the cap structure 140 shown in FIGS. 1A and 1B), to provide an upper electromagnetic shield layer of the backside multilevel wiring structure 320-1.

It is to be appreciated that the various layers of the exemplary package structure 300 are constructed using low-loss dielectric substrates which allows superconducting quantum devices and circuitry to be integrally packaged together with low-loss multilevel wiring layers. For example, in some embodiments, the thinned dielectric substrates 312s, 320s, 330s, 340s, 350s, and 360s of the package structure 300 are formed of low-loss monocrystalline (single crystal) dielectric material, such as monocrystalline (single crystal) semiconductor material (e.g., monocrystalline silicon) or any suitable low-loss (high resistivity) dielectric material (e.g., resistivity of greater than 500 ohms-centimeter (Ω·cm)) such as single crystal Al₂O₃, single crystal MgO, single crystal SiO₂, and other types of single crystal dielectric materials which are suitable for the given application. For the exemplary package structure 300 (as well as the other exemplary package structures 100 and 200), the thickness of thinned dielectric substrates 312s, 320s, 330s, 340s, 350s, and 360s (TSV layers) of the package structure 300 can be substantially reduced, e.g., in a range of 50 microns to 100 microns, or even less than 50 microns. However, the thickness of the thinned dielectric substrates of the quantum chips (e.g., quantum chips 120 and 320) is critical to prevent undue capacitive loading of the superconducting qubits to the ground plane (e.g., first ground shield 390). Moreover, while exemplary embodiments have been discussed in the context of implementing the backend horizontal wiring of the qubit couplers and other signal wiring as CPW transmission lines, it is to understood that in order to achieve a desired characteristic impedance (e.g., 50 ohm impedance) on the wiring levels, any suitable combination CPW and stripline transmission line geometries can be implemented, to achieve the desired characteristic impedance. In this regard, there is significant freedom to select the desired thicknesses of thinned dielectric substrates 330s, 340s, 350s, and 360s (TSV layers) of the package structure 300.

It is to be appreciated that exemplary package structure 300 comprises an integrated electromagnetic shielding structure which provides a well-defined microwave environment for the quantum devices, circuit components, and the backend wiring of the package structure 300. For example, as specifically shown in FIG. 3, each of the layers 330, 340, 350, and 360 can be fabricated with respective via fences formed by respective ground TSVs in the respective thinned dielectric substrates 330s, 340s, 350s, and 360s. In addition, the first and second ground shields 390 and 392, and the upper ground shield provided by the second metallization layer 362, together with the ground via fences formed in the outer perimeter regions of the respective thinned dielectric substrates 330s, 340s, 350s, and 360s, collectively provide enclosed microwave environments which isolate and shield the first and second qubit coupler 380 and 385 (and other signal wiring) from electromagnetic interference with each other and from the external environment, while also shielding backside wiring of, e.g., the first and second qubit couplers 380 and 385 from the superconducting qubits and quantum circuitry on the frontside of the quantum chip 320.

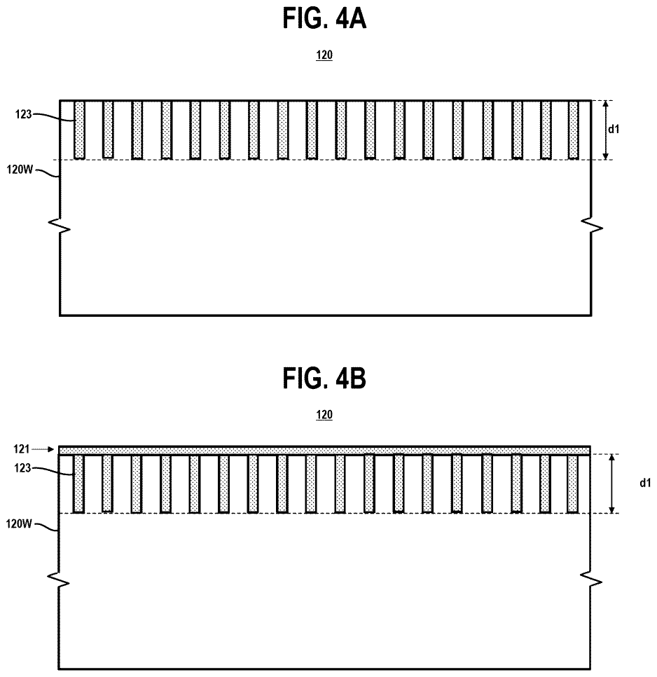

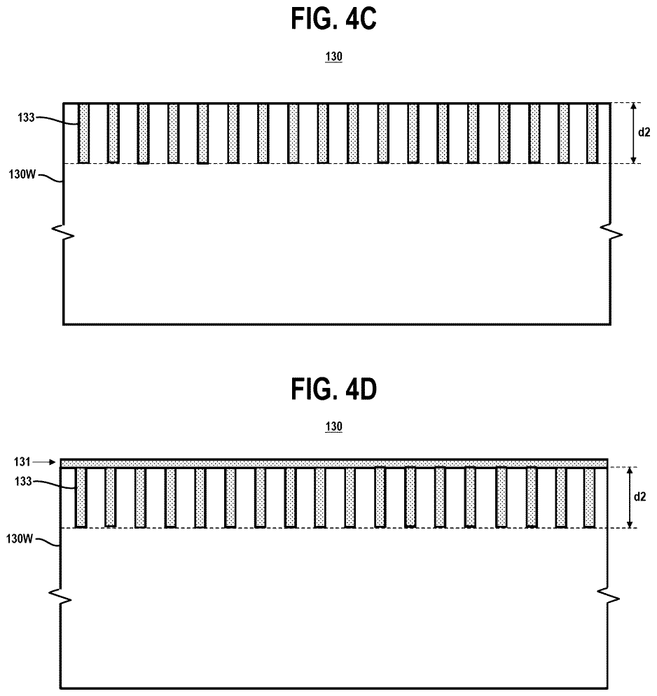

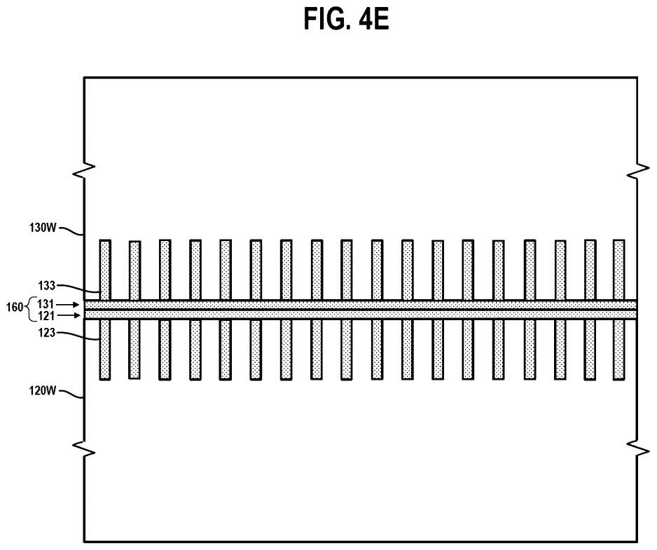

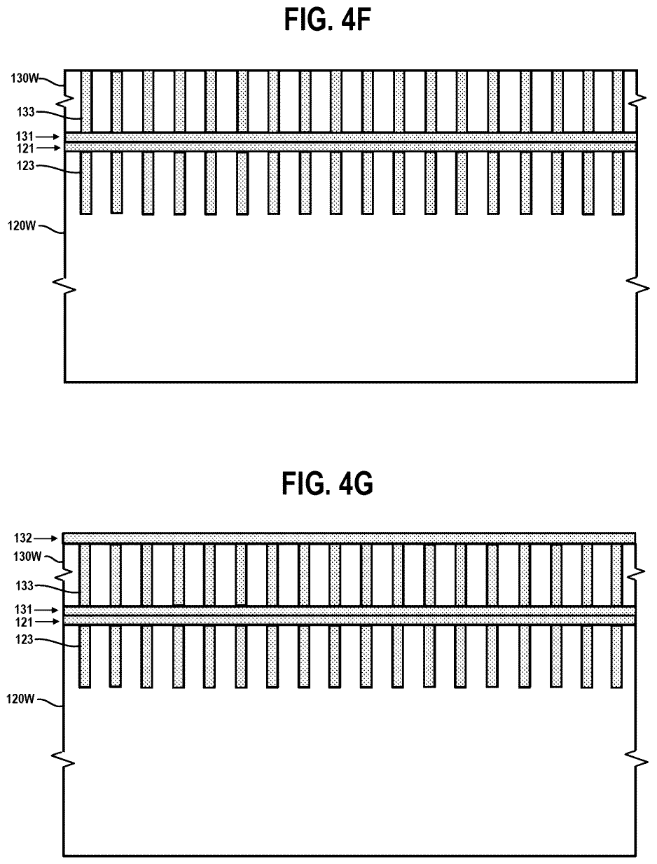

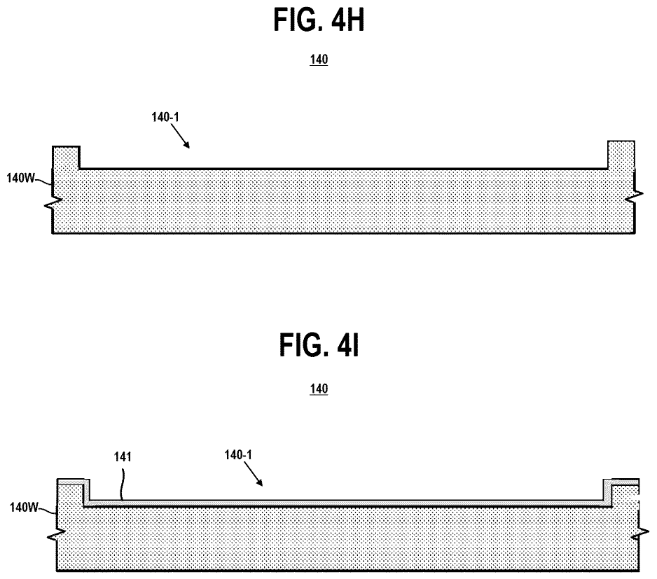

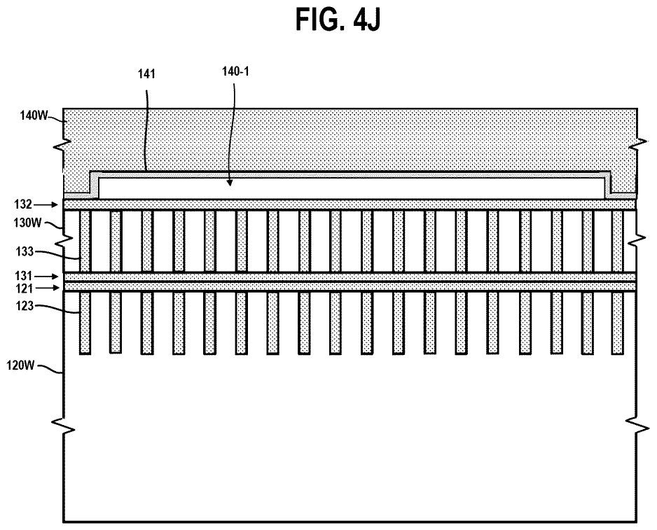

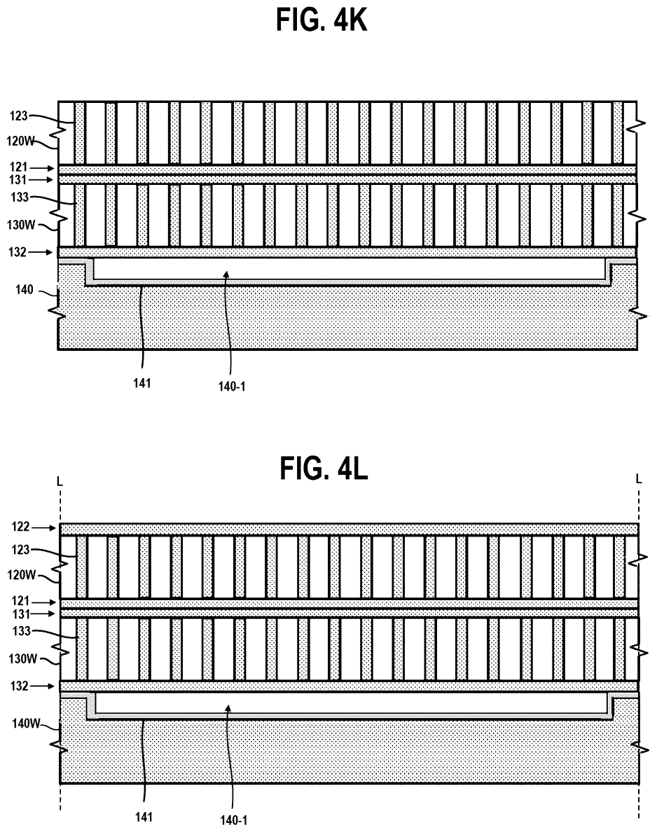

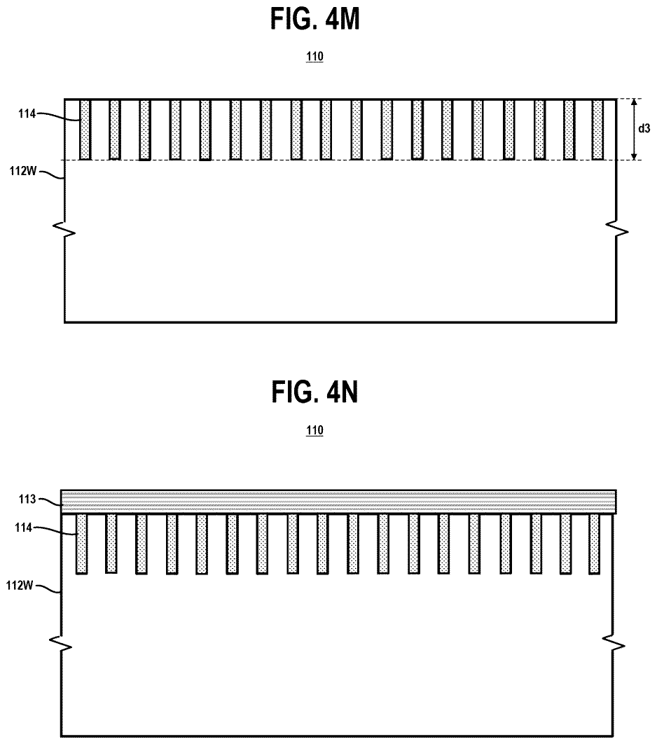

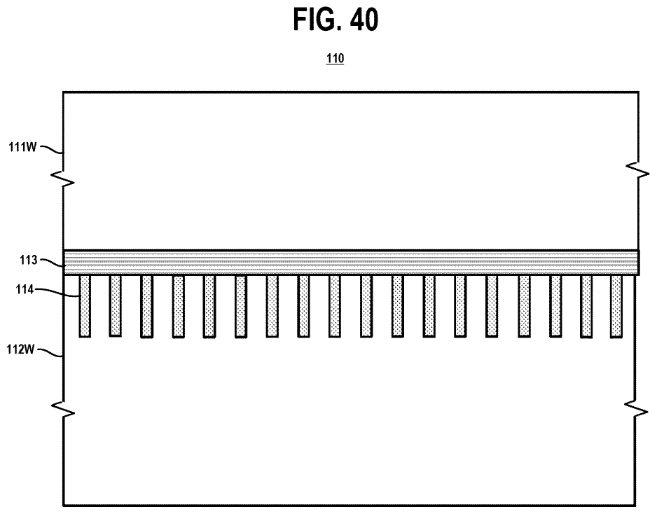

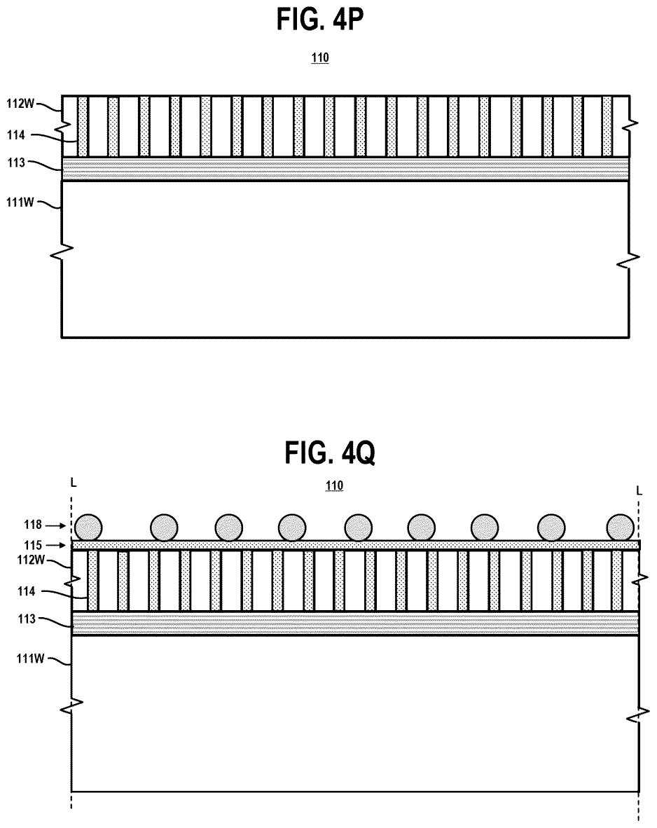

FIGS. 4A through 4Q schematically illustrate a method for fabricating a quantum chip package structure which comprises a low-loss multilevel wiring structure with integrated electromagnetic shielding, according to an exemplary embodiment of the disclosure. In particular, for the purpose of illustration, FIGS. 4A through 4Q schematically illustrate a method for fabricating the exemplary quantum chip package structure 100 discussed above in conjunction with FIGS. 1A-1C. In this regard, 4A through 4Q schematically illustrate various process steps for fabricating the interposer 110, the quantum chip 120, and the various layers of the backside multilevel wiring structure 120-1, and bonding/connecting such components to form the exemplary quantum chip package structure 100.

To begin, FIGS. 4A and 4B schematically illustrate initial processing steps for fabricating the quantum chip 120 of the exemplary package structure 100. In particular, FIG. 4A schematically illustrates an intermediate stage of fabrication in which a first wafer 120W is processed to form a plurality of vias 123 in a surface of the first wafer 120W. In some embodiments, the vias 123 are formed to a depth d1 which corresponds to a desired thickness of the thinned dielectric substrate 120s of the quantum chip 120, where the bottom end portions of the vias 123 are embedded at a depth d1 within the first wafer 120W. Next, FIG. 4B schematically illustrates an intermediate stage of fabrication after forming the first metallization layer 121 on the surface of the first wafer 120W in contact with the vias 123. While not specifically shown in FIG. 4B, as noted above, the first metallization layer 121 would comprise patterned metal features such as a ground plane and TSV landing pads. Moreover, in some embodiments, a thin layer of bonding metal can be formed on the surface of the first metallization layer, if desired, to facilitate a metal-to-metal bonding process, as described in further detail below.

In some embodiments, the first wafer 120W comprises a semiconductor wafer that is formed of a monocrystalline semiconductor material, such as monocrystalline silicon. In other embodiments, the first wafer 120W can be formed with other types of low-loss (high resistivity) monocrystalline dielectric material, which is suitable for fabricating a quantum chip. The first metallization layer 121 and the vias 123 can be formed of any suitable superconducting metal (e.g., Al, Nb, Ta, Ti, W, Sn, Mo, or nitrides thereof, etc.). In some embodiments, one or more layers of bonding metal can be formed on the first metallization layer 121 to facilitate metal-to-metal bonding (e.g., eutectic bonding). For example, in an exemplary embodiment where the first metallization layer 121 is formed of niobium (Nb), a thin layer of titanium nitride (TiN) can be deposited on the niobium metallization layer, and a thin layer of titanium can be deposited on the TiN layer. In this instance, the bonding metal can comprise a TiN/Ti stack.

In some embodiments, the vias 123 and the first metallization layer 121 are formed using separate process steps. For example, in some embodiments, the vias 123 are fabricated by a process which comprises, but not limited to, (i) etching a plurality of via holes in the surface of the first wafer 120W, (ii) depositing a layer of superconducting metal to overfill the via holes with superconducting metal, and (iii) removing the excess (overburden) superconducting metal by performing, e.g., a chemical-mechanical planarization (CMP) process to planarize down to the upper surface of the first wafer 120W and leaving the superconducting metal within the via holes to thereby form the vias 123. The first metallization layer 121 is then formed by a processing which comprises (i) depositing a layer of superconducting metal on the planarized surface of the first wafer 120W, and (ii) patterning the deposited layer of superconducting metal using photolithography techniques to form the first metallization layer 121 with the desired patterned features (e.g., ground plane, TSV landing pads, etc.). The superconducting metal can be deposited using known techniques including, but not limited to, physical vapor deposition (PVD) (e.g., evaporation, sputtering), electroplating, or chemical vapor deposition (CVD), etc.

In some embodiments, the vias 123 and the first metallization layer 121 can be separately or concurrently fabricated using a single damascene process or a dual damascene process. In this instance, the patterned features of the first metallization layer 121 would be formed in patterned trenches that are etched in the surface of the first wafer 120W. The damascene process can be utilized to achieve a planar surface with the first metallization layer 121 embedded in the upper surface of the first wafer 120W (as opposed to the first metallization layer 121 being disposed on top of the upper surface of the first wafer 120W). For example, in some embodiments, the first metallization layer 121 and vias 123 can be formed by performing a dual damascene process which comprises: (i) patterning the surface of first wafer 120W to form via holes and trenches in the surface of the first wafer 120W, which define the desired pattern of vias and metal features of the first metallization layer 121; (ii) depositing a layer of superconducting metal to overfill the via holes and trenches with superconducting metal; and (iii) removing the excess (overburden) superconducting metal by performing, e.g., a CMP process to planarize down to the upper surface of the first wafer 120W, and leaving the superconducting metal within the trenches and via holes to thereby form the first metallization layer 121 and vias 123. The superconducting metal can be deposited using known techniques including, but not limited to, PVD (e.g., evaporation, sputtering), CVD, electroplating, etc.

Next, FIGS. 4C and 4D schematically illustrate initial processing steps for fabricating the first layer 130 of the exemplary package structure 100. In particular, FIG. 4C schematically illustrates an intermediate stage of fabrication in which a second wafer 130W is processed to form a plurality of vias 133 in a surface of the second wafer 130W. In some embodiments, the vias 133 are formed to a depth d2 which corresponds to a desired thickness of the thinned dielectric substrate 130s of the first layer 130, where the bottom end portions of the vias 133 are embedded at the depth d2 within the second wafer 130W. Next, FIG. 4D schematically illustrates an intermediate stage of fabrication after forming the first metallization layer 131 on the surface of the second wafer 130W in contact with the vias 133. While not specifically shown in FIG. 4D, as noted above, the first metallization layer 131 of the first layer 130 would comprise patterned metal features such as a ground plane and TSV landing pads. Moreover, in some embodiments, a thin layer of bonding metal can be formed on the surface of the first metallization layer, if desired, to facilitate a metal-to-metal bonding process, as described in further detail below.

In some embodiments, the second wafer 130W is formed of the same or similar low-loss monocrystalline dielectric material as the first wafer 120W, such as a monocrystalline semiconductor material (e.g., monocrystalline silicon). The first metallization layer 131 and the vias 133 are formed of a suitable superconducting metal. In some embodiments, one or more layers of bonding metal can be formed on the first metallization layer 131 to facilitate metal-to-metal bonding (e.g., eutectic bonding), as discussed above.

Next, FIG. 4E schematically illustrates an intermediate stage of fabrication after bonding the first wafer 120W and the second wafer 130W together using a metal-to-metal bonding process. In some embodiments, the first metallization layers 121 and 131 have the same or similar footprint area and patterned features (e.g., ground planes and TSV landing pads), and are configured to enable metal-to-metal bonding of the first and second wafers 120W and 130W. As schematically shown in FIG. 4E, the bonding of the first metallization layers 121 and 131 results in the formation of the ground shield 160 of the exemplary package structure 100 of FIGS. 1A-1C.

The metal-to-metal bonding can be implemented using any suitable bonding process, depending on the types of superconducting metals used to form the metallization layers. For example, in some embodiments, a low-temperature UHV (ultrahigh vacuum) bonding process can be implemented which is configured to enable in situ surface preparation (to remove oxide) and metal-to-metal bonding (e.g., direct diffusion bonding) at a low temperature, e.g., in a range of about 100° C. to 400° C., depending on the type of superconducting metal. In some embodiments, when the first metallization layers 121 and 131 are formed of aluminum, a diffusion bonding process can be performed to enable direct aluminum-to-aluminum bonding of the first and second wafers 120W and 130W.

In other embodiments, the first metallization layers 121 and 131 can have thin layers of bonding metals formed thereon to enable eutectic metal-to-metal bonding by the formation of an intermediate metal layer (e.g., eutectic metal alloy) which serves as the bonding metallization for metal-to-metal bonding of the first and second wafers 120W and 130W. Each of the layers are bonded using superconducting connections between layers, using a variety of standard techniques such as eutectic bonding or metal-to-metal bonding of materials such as aluminum or other materials. It is to be noted that for some metal-to-metal bonding processes, there can be thin non-superconducting layers which are used to implement the metal-to-metal bonding, (e.g., to promote bonding, to prevent oxidation, etc.). However, despite the use of such thin non-superconducting layers to facilitate metal-to-metal bonds, such metal bonds will have low or zero resistance in the connection as a result of, e.g., the cleanliness of the materials used, the superconducting proximity effect phenomena, etc.

As schematically shown in FIG. 4E, the bonding of the first metallization layers 121 and 131 results in the formation of the ground shield 160 of the exemplary package structure 100 of FIGS. 1A-1C.

Next, FIGS. 4F and 4G schematically illustrate processing steps to complete the formation of the first layer 130 of the package structure 100. In particular, FIG. 4F schematically illustrates an intermediate stage of fabrication of the package structure after performing a wafer thinning process to thin down the backside of the second wafer 130W to reveal the vias 133. It is to be noted that the backside etching of the second wafer 130W can be performed using any suitable via reveal etch process which includes any combination of sequential etch steps including, e.g., wafer griding, dry etch, and/or wet etch steps, or a single etch step. In this instance, the via reveal etch process utilizes the embedded vias 133 as an etch termination point to achieve target thickness of the thinned dielectric substrate 130s of the first layer 130. In some embodiments, the second wafer 130W can have an initial thickness of 700-800 microns or 300 microns, wherein the backside wafer thinning is performed to thin down the second wafer 130W to a desired thickness of the thinned dielectric substrate 130s of the first layer 130. As noted above, the thinned dielectric substrate 130s can have a thickness in a range of about 10 microns to about 100 microns.

Further, FIG. 4G schematically illustrates an intermediate stage of fabrication after forming the second metallization layer 132 on the surface of the thinned second wafer 130W in contact with the vias 133. While not specifically shown in FIG. 4F, as noted above, the second metallization layer 132 would comprise patterned metal features such as a ground plane and horizontal wire segments of one or more qubit couplers (e.g., the horizontal wire segment 150d of the qubit coupler 150, as shown in FIG. 1A), etc. Moreover, in some embodiments, a thin layer of bonding metal can be formed on a portion of the second metallization layer 132 to facilitate metal-to-metal bonding with a second layer (e.g., the cap structure 140). The second metallization layer 132 is formed by depositing and patterning a superconducting metal using techniques using suitable techniques such as described herein.

Next, FIGS. 4H and 4I schematically illustrate processing steps to fabricate the cap structure 140 of the package structure 100. In an exemplary embodiment, as noted above, the cap structure 140 is formed from a wafer of dielectric material which is the same or similar to the dielectric material of the thinned dielectric substrates of the quantum chip and backside wiring layer(s) of the package structure 100. For example, FIG. 4H schematically illustrates an intermediate stage of fabrication in which a third wafer 140W is processed by etching the cavity 140-1 in a surface thereof. While only one cavity is shown in FIG. 4H, it is to be understood that additional cavities could be etched in other regions of the third wafer 140W to form the same or similar cap structures for other package structures.

Further, FIG. 4I schematically illustrates an intermediate stage of fabrication after forming a conformal metallization layer 141 on the surface of the third wafer 140W (or cap wafer 140W) to line the etched cavity 140-1 with metal. As noted above, the metallization layer 141 comprises a ground plane with serves as an upper ground shield of the backside multilevel wiring structure 120-1 of the package structure 100. The metallization layer 141 can include one or more layers of metallic material to provide the electromagnetic shielding. For example, the one or more layers of metallic materials of the metallization layer 141 can include a metal layer such as gold (Au), palladium (Pd), silver (Ag), etc., or other types of metal/metallic material with electrical properties that are suitable to provide electromagnetic shielding, e.g., capable of reflecting RF/microwave radiation. While gold, silver and crystalline palladium are sufficient metallic materials for reflecting RF/microwave radiation, such materials may be insufficient to provide magnetic shielding. In this regard, the metallization layer 141 will be formed with a layer of superconducting metallic material to provide magnetic shielding. Furthermore, in some embodiments, a thin layer of bonding metal can be formed on surface regions of the metallization layer 141 to facilitate metal-to-metal bonding of the third wafer 140W to the thinned second wafer 130W.

Next, FIGS. 4J, 4K, and 4L schematically illustrate processing steps to complete the fabrication of the quantum chip 120 and the backside multilevel wiring structure 120-1 of the package structure 100. In particular, FIG. 4J schematically illustrates an intermediate stage of fabrication of the package structure in which the third wafer 140W (cap wafer) is aligned and bonded to the thinned second wafer 130W using a metal-to-metal bonding process. The bonding process is performed by metal-to-metal bonding a portion of metallization layer 141 of the third wafer 140W to the ground plane of the second metallization layer 132 of the thinned second wafer 130W. The metal-to-metal bonding is performed using any suitable bonding techniques such as described herein.

Next, FIG. 4K schematically illustrates an intermediate stage of fabrication of the package structure after performing a wafer thinning process to thin down the backside of the first wafer 120W to reveal the vias 123. The backside etching of the first wafer 120W can be performed using any suitable via reveal etch process, such as described herein. In this instance, the first wafer 120W can have an initial thickness of 700-800 microns or 300 microns, wherein the via reveal etch process performed using the embedded vias 123 as an etch termination point to achieve target thickness of the thinned dielectric substrate 120s of the quantum chip 120.

Further, FIG. 4L schematically illustrates an intermediate stage of fabrication after forming the second metallization layer 122 on a surface of the thinned first wafer 120W in contact with the vias 123. While not specifically shown in FIG. 4L, as noted above, the second metallization layer 122 would comprise patterned metal features such as a ground plane, horizontal wire segments of one or more qubit couplers, superconducting capacitor pads of qubits, qubit readout resonators, UBM pads, etc. Furthermore, additional processing steps at this stage are performed to fabricate Josephson junctions and thereby form superconducting qubits and other quantum devices, etc. Thereafter, the wafer stack shown in FIG. 4L is diced to separate stack structures, each comprising a quantum chip and backside multilevel wiring structure. For example, the wafer stack of FIG. 4L is diced along dicing lines (shown as dashed lines L) to singulate the exemplary stack structure comprising the quantum chip 120 and backside multilevel wiring structure 120-1 as shown FIGS. 1A and 1B.

Next, FIG. 4M though 4Q schematically illustrate processing steps to form the interposer 110 of the package structure 100, as shown in FIGS. 1A and 1B. In particular, FIG. 4M schematically illustrates an intermediate stage of fabrication of an interposer wafer stack in which a first wafer 112W (or first interposer wafer 112W) is processed to form a plurality of vias 114 in a frontside surface of the first wafer 112W. In some embodiments, the vias 114 are formed to a depth d3 which corresponds to a desired thickness of the thinned dielectric substrate 112s of the interposer 110, where the bottom end portions of the vias 114 are embedded at a depth d3 below the frontside surface of the first wafer 112W.

Further, FIG. 4N schematically illustrates an intermediate stage of fabrication of the interposer wafer stack after forming a multilevel wiring structure 113 on the frontside surface of the first wafer 112W. The multilevel wiring structure 113 comprises alternating layers of deposited dielectric material (interlayer dielectric layers) and metallization layers, and interlayer vias, which are formed using suitable techniques, such as back end of line (BEOL) fabrication techniques. Next, FIG. 4O schematically illustrates an intermediate stage of fabrication of the interposer wafer stack after bonding a second wafer 111W (e.g., a support (handle) wafer 111W) to the multilevel wiring structure 113 on the frontside of the first wafer 112W. The second (support) wafer 111W can be bonded to the multilevel wiring structure 113 using a layer of bonding adhesive which is suitable for such bonding.

Next, FIG. 4P schematically illustrates an intermediate stage of fabrication of the interposer wafer stack after performing a wafer thinning process to thin down the backside of the first wafer 112W to reveal the vias 114. The backside etching of the first wafer 112W can be performed using any suitable via reveal etch process which includes any combination of sequential etch steps including, e.g., wafer griding, dry etch, and/or wet etch steps, or a single etch step. In some embodiments, the first wafer 112W can have an initial thickness of 700-800 microns or 300 microns, wherein the backside wafer thinning is performed to thin down the first wafer 112W to a desired thickness of the thinned dielectric substrate 112s of the interposer 110 of the package structure 100 as shown in FIGS. 1A and 1B, wherein the thinned dielectric substrate 112s can have a thickness in a range of about 10 microns to about 100 microns.

Further, FIG. 4Q schematically illustrates an intermediate stage of fabrication of the interposer wafer stack after forming the metallization layer 115 on the surface of the thinned first wafer 112W in contact with the vias 114, and after forming the solder bumps 118 (e.g., indium solder bumps) on bump pads of the metallization layer 115. While not specifically shown in FIG. 4Q, as noted above, the metallization layer 115 would comprise patterned metal features including, but not limited to, a ground plane, planar transmission lines, resonators, UBM bump pads, etc. After the completing the fabrication of the interposer wafer stack as shown in FIG. 4Q, the interposer wafer stack is diced along dicing lines (shown as dashed lines L) to singulate the exemplary interposer 110 shown in FIGS. 1A and 1B. Therefore, the stack structure comprising the quantum chip 120 and backside multilevel wiring structure 120-1 as shown FIGS. 1A and 1B is flip-chip bonded to the interposer 110 via the solder bumps 118, using any suitable flip-chip bonding process, thereby resulting in the exemplary package structure 100 as shown in FIGS. 1A and 1B.

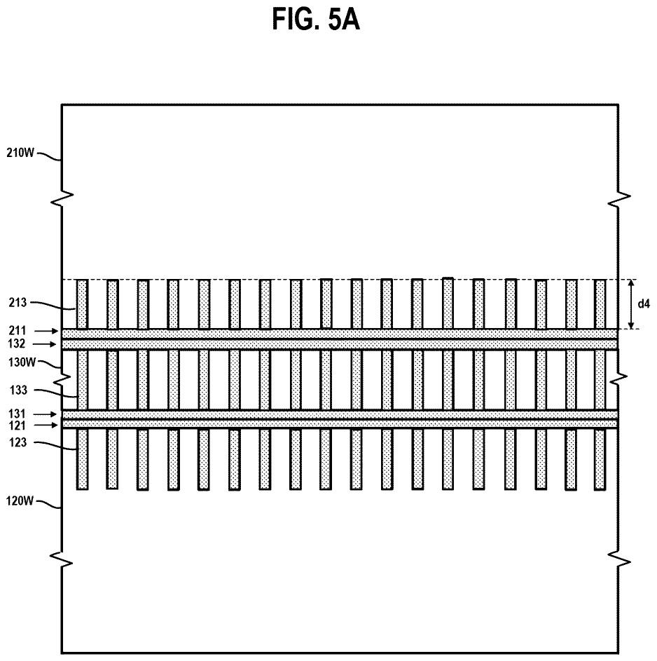

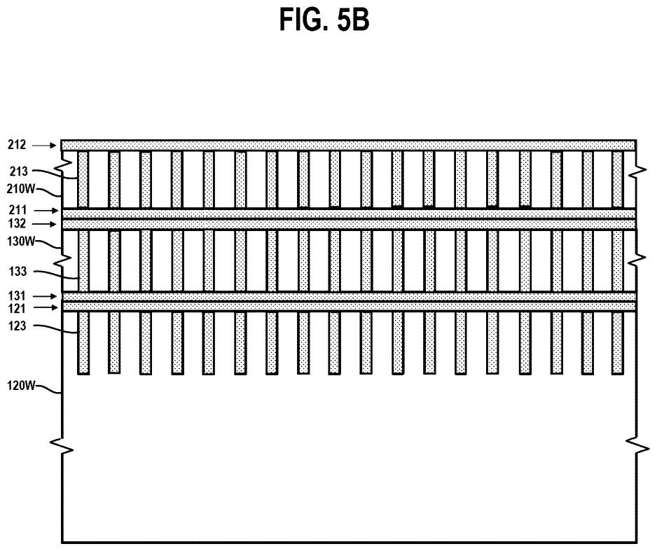

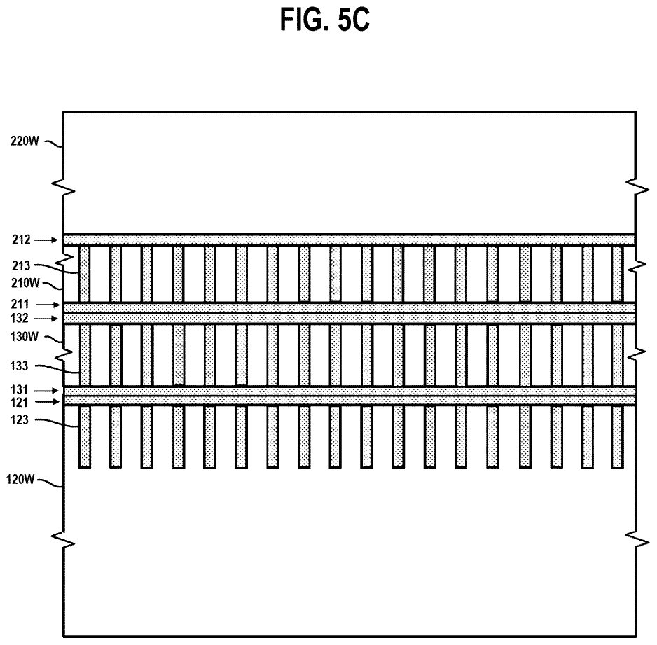

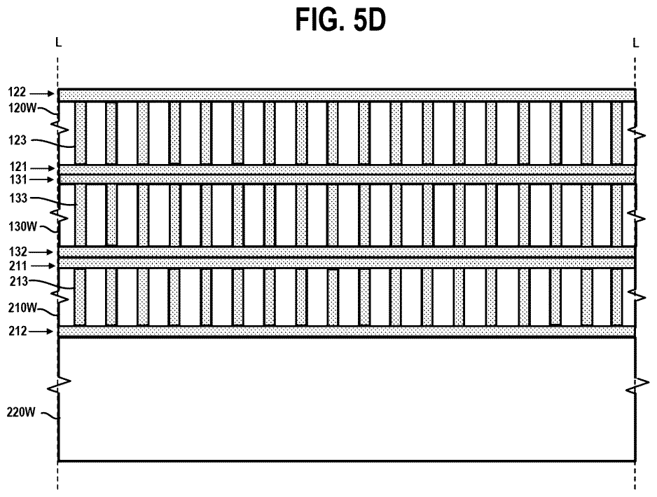

FIGS. 5A through 5D schematically illustrate a method for fabricating a quantum chip package structure which comprises a low-loss multilevel wiring structure with integrated electromagnetic shielding, according to another exemplary embodiment of the disclosure. In particular, for purposes of illustration, FIGS. 5A through 5D schematically illustrate a method for fabricating the exemplary quantum chip package structure 200 discussed above in conjunction with FIGS. 2A and 2B. It is to be noted that the initial processing stages for fabricating the quantum chip package structure 200 are the same as the initial processing stages shown and discussed above in conjunction with FIGS. 4A through 4G, the details of which will not be repeated. In this regard, FIGS. 5A through 5D schematically illustrate various process steps for fabricating the stacked structure comprising the quantum chip 120, and the backside multilevel wiring structure 120-2 of the exemplary quantum chip package structure 200.

In particular, FIG. 5A schematically illustrates an intermediate stage of fabrication after forming the exemplary structure shown in FIG. 4G and after bonding a third wafer 210W to the second wafer 130W using a metal-to-metal bonding process. The third wafer 210W comprises a plurality of vias 213 formed in frontside of the third wafer 210W, and a first metallization layer 211 formed on the frontside surface of the third wafer 210W in contact with the vias 213, using the same or similar fabricating method as discussed above. In some embodiments, the vias 213 are formed to a depth d4 which corresponds to a desired thickness of the thinned dielectric substrate 210s of the second layer 210 of the backside multilevel wiring structure 120-2 shown in FIGS. 2A and 2B. The bottom end portions of the vias 213 are embedded at the depth d4 within the frontside of the third wafer 210W. In some embodiments, the third wafer 210W is formed of the same or similar low-loss monocrystalline dielectric material as the first wafer 120W and the second wafer 130W.

While not specifically shown in FIG. 5A, as noted above, in some embodiments, the first metallization layer 211 of the second layer 210 would comprise a patterned ground plane having a footprint which corresponds to that of the patterned ground plane of the second metallization layer 132 of the second wafer 130W. Moreover, in some embodiments, a thin layer of bonding metal can be formed on the surface of the first metallization layer 211, if desired, to facilitate a metal-to-metal bonding process. As schematically shown in FIG. 5A, the second wafer 130W and the third wafer 210W are bonded together by metal-to-metal bonding the respective metallization layers 132 and 211, using a suitable metal bonding technique such as described herein.

Next, FIG. 5B schematically illustrates an intermediate stage of fabrication of the package structure after performing a wafer thinning process to thin down the backside of the third wafer 210W to reveal the vias 213, and after forming the second metallization layer 212 on the backside surface of the thinned third wafer 210W in contact with the revealed vias 213. As noted above, backside etching of the third wafer 210W can be performed using any suitable via reveal etch process which includes any combination of sequential etch steps including, e.g., wafer griding, dry etch, and/or wet etch steps, or a single etch step. In some embodiments, the third wafer 210W can have an initial thickness of 700-800 microns or 300 microns, wherein the backside wafer thinning is performed to thin down the third wafer 210W to a desired thickness of the thinned dielectric substrate 210s of the second layer 210. As noted above, the second metallization layer 212 comprises a ground plane which serves as upper ground shield of the exemplary low-low multilevel wiring structure 120-2 of the package structure 200 as shown in FIGS. 2A and 2B.

Next, FIG. 5C schematically illustrates an intermediate stage of fabrication of the package structure after bonding a support (handle) wafer 220W to the thinned third wafer 210W. The support wafer 220W is utilized to provide structural integrity to the wafer stack when performing subsequent processing steps. For example, FIG. 5D schematically illustrates an intermediate stage of fabrication of the package structure after performing a wafer thinning process to thin down the backside of the first wafer 120W to reveal the vias 123, and after forming the second metallization layer 122 on the backside surface of the thinned first wafer 120W in contact with the revealed vias 123. As noted above, backside etching of the first wafer 120W can be performed using any suitable via reveal etch process which includes any combination of sequential etch steps including, e.g., wafer griding, dry etch, and/or wet etch steps, or a single etch step. In some embodiments, the first wafer 120W can have an initial thickness of 700-800 microns or 300 microns, wherein the backside wafer thinning is performed to thin down the first wafer 120W to a desired thickness of the thinned dielectric substrate 120s of the quantum chip 120.

While not specifically shown in FIG. 5D, as noted above, the second metallization layer 122 would comprise patterned metal features such as a ground plane, horizontal wire segments of one or more qubit couplers, superconducting capacitor pads of qubits, qubit readout resonators, UBM pads, etc. Furthermore, additional processing steps at this stage are performed to fabricate Josephson junctions and thereby form superconducting qubits and other quantum devices, etc. Thereafter, the wafer stack shown in FIG. 5D is diced into separate stack structures, each comprising a quantum chip and backside multilevel wiring structure. For example, the wafer stack of FIG. 5D is diced along dicing lines (shown as dashed lines L) to singulate the exemplary stack structure comprising the quantum chip 120 and backside multilevel wiring structure 120-2 as shown FIGS. 2A and 2B. Next, the interposer 110 can be fabricated and bonded to the singulated stack structure comprising the quantum chip 120 and backside multilevel wiring structure 120-2, using the same techniques as discussed above in conjunction with FIGS. 4J through 4Q, the details of which need not be repeated.

It is to be noted that the exemplary quantum package structure 300 of FIGS. 3A and 3B can be fabricated using the same methods as discussed above in conjunction with FIGS. 4A through 4A and FIGS. 5A through 5D. As noted above, the metallization layers in the backside multilevel wiring structure 320-1 of the exemplary quantum package structure 300 are formed using single or dual damascene methods as discussed above, wherein the patterned features (e.g., ground planes, horizontal wiring (e.g., qubit couplers), etc., of the metallization layers are formed in trenches such that the patterned features are embedded in the surface of the thinned dielectric substrates, and not formed on top of the surfaces of the thinned dielectric substrates. In this configuration, the surfaces of the various layers of the backside multilevel wiring structure are planar and bonded together with no empty space therebetween, which allows the vertical wire segments of the qubit couplers to be fabricated using continuous TSVs that extend through two or more layers of package structure.

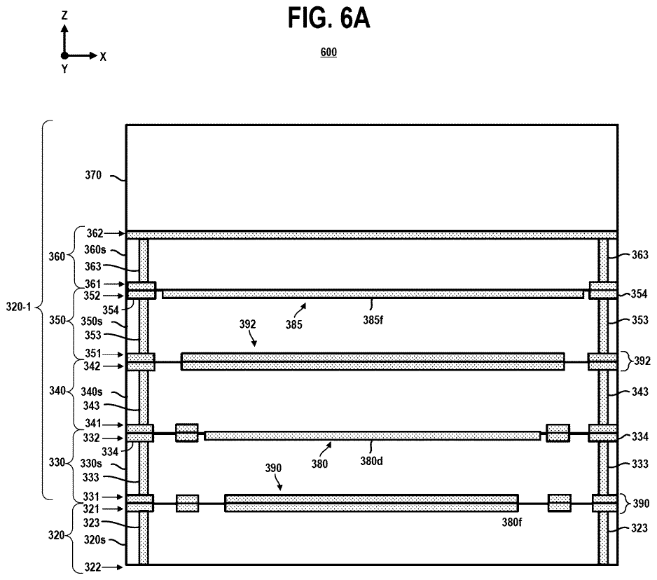

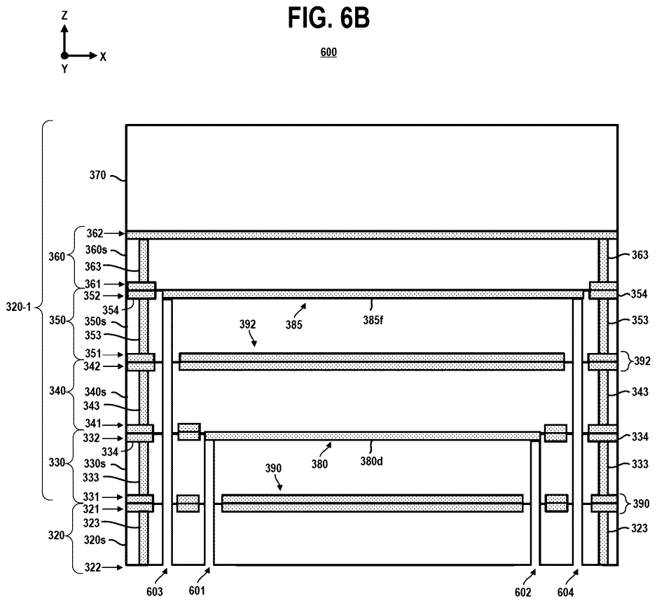

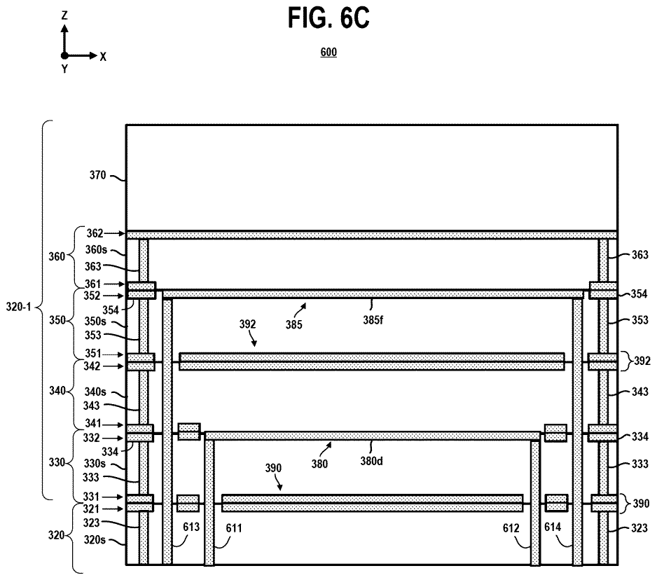

FIGS. 6A through 6C schematically illustrate a method for fabricating a quantum chip package structure which comprises a low-loss multilevel wiring structure with integrated electromagnetic shielding, according to another exemplary embodiment of the disclosure. In particular, FIGS. 6A through 6C schematically illustrate a method for fabricating a quantum chip package structure wherein vertical wire segments of qubit couplers are fabricated using continuous TSVs that extend through two or more layers of the package structure. For purposes of illustration, FIGS. 6A through 6D schematically illustrate a method for fabricating an alternate embodiment of the exemplary quantum chip package structure 300 discussed above in conjunction with FIGS. 3A and 3B, which comprises the quantum chip 320, and a backside multilevel wiring structure 320-1 disposed on a backside of the quantum chip 320 which comprises first, second, third, and fourth layers 330, 340, 350, and 360, and the optional support (handle) substrate 370.

FIG. 6A is a schematic cross-sectional view of a wafer stack 600 at an intermediate stage of fabrication after thinning down a first wafer to reveal the ground vias 323 and form the thinned dielectric substrate 320s of the quantum chip 320. FIG. 6A shows a portion of the wafer stack 600 which comprises the quantum chip 320 and backside multilevel wiring structure 320-1 at intermediate stages of fabrication before forming the second metallization layer 322 and superconducting quantum bits and circuit components of the quantum chip 320 on the bottom surface of the thinned dielectric substrate 320s, and before forming vertical wire segments of the first and second qubit couplers 380 and 385. In particular, at the intermediate stage of fabrication as shown in FIG. 6A, the various layers 320, 330, 340, and 350 do not include individual TSVs that form the vertical wire segments of the first and second qubit couplers 380 and 385, while the horizontal wire segments 380d and 385f of the respective first and second qubit couplers 380 and 385 are formed as patterned features of the respective metallization layers 332 and 352. Moreover, as shown in FIG. 6A, the various ground planes of the metallization layers 321, 331, 332, 341, 342, and 351 have discontinuities in regions where continuous TSVs are formed to extend through the chips layers to provide the vertical wiring of the first and second qubit couplers 380 and 385.

FIG. 6B is a schematic cross-sectional view of the wafer stack 600 at an intermediate stage of fabrication after forming a plurality of via holes 601, 602, 603, and 604 which extend through the thinned dielectric substrates 320s, 330s, 340s, and 350s of multiple layers of the wafer stack 600 to expose end portions of horizontal wire segments 380d and 385f of the first and second qubit couplers 380 and 385 in metallization layers of the wafer stack 600. In particular, as schematically illustrated in FIG. 6B, the via holes 601 and 602 are formed to extend through the thinned dielectric substrates 320s and 330s to expose end portions of the horizontal wire segment 380d of the first qubit coupler 380. The via holes 603 and 604 are formed to extend through the thinned dielectric substrates 320s, 330s, 340s, and 350s to expose end portions of the horizontal wire segment 385f of the second qubit coupler 385.

FIG. 6C is a schematic cross-sectional view of the wafer stack 600 at an intermediate stage of fabrication after filling the via holes 601, 602, 603, and 604 with a superconducting metal to form continuous TSVs 611, 612, 613, and 614 which extend through the thinned dielectric substrates 320s, 330s, 340s, and 350s of the wafer stack 600, which form vertical wires of the first and second qubit couplers 380 and 385. In particular, in the exemplary wafer stack 600 shown in FIG. 6C, the first qubit coupler 380 comprises the continuous TSVs 611 and 612 (vertical wires), and the horizontal wire segment 380d, while second qubit coupler 385 comprises the continuous TSVs 613 and 614 (vertical wires), and the horizontal wire segment 385f. Advantageously, the formation of the continuous TSVs 611, 612, 613, and 614 as vertical wires of the first and second qubit couplers 380 and 385, eliminates the need for precise alignment of the individual TSVs in the thinned dielectric substrates 320s, 330s, 340s, and 350s to form the vertical wires, and eliminates the need to form corresponding TSV landing pads in the metallization layers for such TSVs.

Following the formation of the continuous TSVs 611, 612, 613, and 614, the second metallization layer 322 would be formed on the surface of the thinned dielectric substrate 320s with patterned metal features such as a ground plane, horizontal wire segments of one or more qubit couplers, superconducting capacitor pads of qubits, qubit readout resonators, UBM pads, etc. Furthermore, additional processing steps at this stage are performed to fabricate Josephson junctions and thereby form superconducting qubits and other quantum devices, etc. Thereafter, the wafer stack 600 is diced into separate stack structures, each comprising a quantum chip and backside multilevel wiring structure with continuous TSVs as vertical wires of the qubit couplers.

It is to be noted that the schematic illustrations of the exemplary package structures 100, 200, 300, and 600 are meant to show general architectures of quantum chip package structures which comprise low-loss multilevel wiring structures with integrated electromagnetic shielding structure, for purposes of discussing and presenting salient inventive concepts of the disclosure. However, it is to be understood that the fabrication methods as discussed herein could be utilized to fabricate multilevel wiring structures that are designed to have specific patterned metallization layers and arrangement of interlayer via connections, as needed, to provide any desired network of wiring and interlevel via connections for a given application.

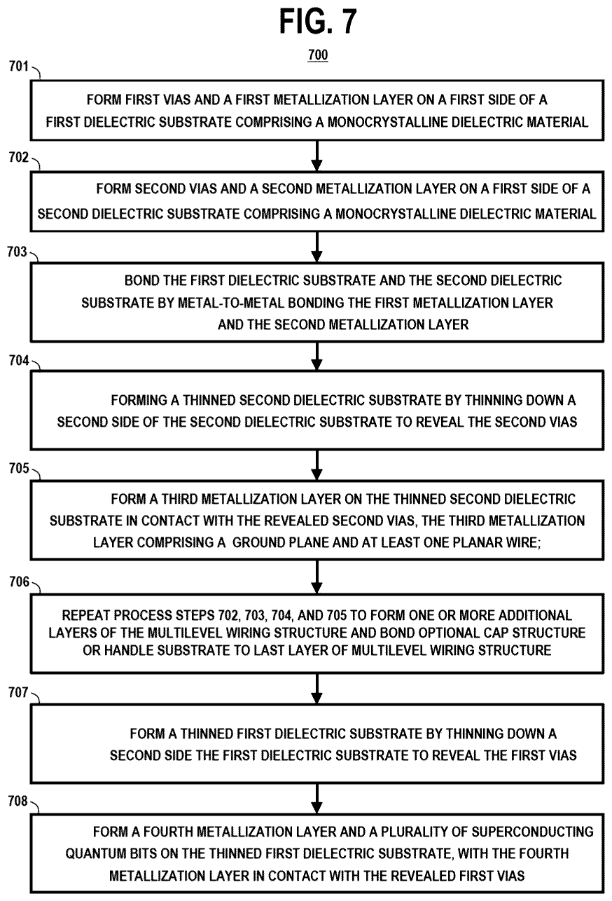

FIG. 7 illustrates a flow diagram of a method for a method for fabricating a quantum chip package structure which comprises a low-loss multilevel wiring structure with integrated electromagnetic shielding, according to another exemplary embodiment of the disclosure. In particular, the flow diagram of FIG. 7 depicts a high-level fabrication process 700 for constructing a quantum chip package structure, which is based on the exemplary fabrication processes discussed above in conjunction with, e.g., FIGS. 4A-4Q, FIGS. 5A-5D, and FIGS. 6A-6C. The fabrication process 700 comprises forming first vias and a first metallization layer on a first side of a first dielectric substrate comprising a monocrystalline dielectric material (block 701), forming second vias and a second metallization layer on a first side of a second dielectric substrate comprising a monocrystalline dielectric material (block 702), bonding the first dielectric substrate and the second dielectric substrate by metal-to-metal bonding the first metallization layer and the second metallization layer (block 703), forming a thinned second dielectric substrate by thinning down a second side of the second dielectric substrate to reveal the second vias (block 704), and forming a third metallization layer on the thinned second dielectric substrate in contact with the revealed second vias, the third metallization layer comprising a ground plane and at least one planar wire (block 705). In some embodiments, the process steps of blocks 701 and 704 are the same or similar to the fabrication process flow as schematically illustrated and discussed above in conjunction with FIGS. 4A through 4G.

Next, the process steps of block 702, 703, 704, and 705 can be repeated one or more times to form one or more additional layers (e.g., wring layer, and optional upper EMI shielding layer) of the backend low-loss multilevel wiring structure and bond an optional cap structure or handle substrate to last layer of multilayer wiring structure (block 706). For example, in some embodiments, the process flow of block 706 is the same or similar to the fabrication process steps schematically illustrated and discussed above in conjunction with, e.g., FIG. 4J or FIGS. 5A, 5B, 5C and 5D.

The fabrication process then proceeds to complete the fabrication of the quantum chip. For example, the process further comprises forming a thinned first dielectric substrate by thinning down a second side the first dielectric substrate to reveal the first vias (block 707), and forming a fourth metallization layer and a plurality of superconducting quantum bits on the thinned first dielectric substrate, with the fourth metallization layer in contact with the revealed first vias (block 708). For example, in some embodiments, the process flow of blocks 707 and 708 is the same or similar to the fabrication process steps schematically illustrated and discussed above in conjunction with, e.g., FIGS. 4K and 4L. Moreover, in some embodiments, after performing the wafer thinning process (block 707), the process flow as schematically illustrated in FIGS. 6A, 6B, and 6C can be performed to form the continuous TSVs through the various package substrate layers to form the vertical wiring of qubit coupling buses, as discussed above.

As noted above, the vias and the patterned metallization layers can be fabricated using various methods such as damascene techniques (e.g., single or dual damascene) to form patterned metallization layers which are disposed within the surfaces of the dielectric substrates so that the various layers (e.g., wiring layers and upper EMI shield layers) comprises planar surfaces, resulting in no spaces or voids between two layers that are metal-to-metal bonded. In other embodiments, the patterned metallization layers of multilevel wiring structure can be formed using other methods which include, but are not limited to, subtractive etch methods, sidewall image transfer methods (e.g., spacer formation), etc. Such methods result in the formation of the patterned metallization layers on top of the surfaces of the dielectric substrates.

Advantageously, wafer bonding and wafer thinning techniques are implemented to form multilevel wiring structures having low-loss interlayer dielectric layers. For example, as noted above, the exemplary wafer bonding and wafer thinning techniques allow the formation of low-loss multilevel wiring structures having low-loss monocrystalline dielectric layers (e.g., monocrystalline silicon), which allows a network of signal wiring (e.g., quit coupler buses) to be integrated within such low-loss multilevel wiring structures. This is in contrast to conventional methods for fabricating backend multilevel wiring structures in which interlayer dielectric layers having amorphous or polycrystalline dielectric material are formed using deposition techniques such as CVD or plasma-enhanced (PE) CVD techniques.

Indeed, the integration of signal wiring (e.g., quit coupler buses) within a low-loss backend multilevel wiring structure of a quantum chips allows for greater circuit density in terms of the number of quantum devices per square area, which increases the plausible computational power of quantum processors. Indeed, a smaller horizontal footprint can be achieved by incorporating superconducting qubits at one level (quantum chip) of the package structure, while incorporating and routing a network of qubit couplers including long range qubit couplers in and through the backend low-loss multilevel wiring structure, and possibly decreasing the coupling distance by avoiding Manhattan style routing. By constructing a low-loss multilevel wiring structure having a sufficient number of layers, many quantum device and circuit components can be integrated within the low-loss multilevel wiring structure, thereby allowing further scaling by, e.g., increasing a number of qubit-to-qubit connections using low-loss connections that routed through the low-loss backside multilevel wiring structure. In this regard, incorporating a network of qubit coupling buses within a low-loss backside multilevel wiring structure enables higher connectivity routing and greater quantum circuit density, as well as enable a space saving packing structure that supports continued scaling.

In other embodiments, low-loss multilevel wiring structures with integrated electromagnetic shielding can be fabricated to have one or more layers (e.g., wiring layers) which include inner cavities that are aligned to, and disposed above, transmission lines (e.g., horizontal wire segments of coupler) to achieve higher propagation velocity of signals transmitted on the transmission lines. Indeed, the propagation velocity of a pulse along a transmission line is indirectly proportional to the dielectric constant of the surrounding dielectric material. In this regard, since the inner cavities (air or vacuum,) have a dielectric constant (e.g., about 1.0) which is less than the dielectric constant of a dielectric material such as silicon, the inner cavities provide a decrease in the effective dielectric constant of the material surrounding the transmission lines (as compared to the effective dielectric constant with the transmission lines being disposed between dielectric substrates). A higher propagation velocity is desirable because it makes the transmission lines shorter compared to the signal wavelength.

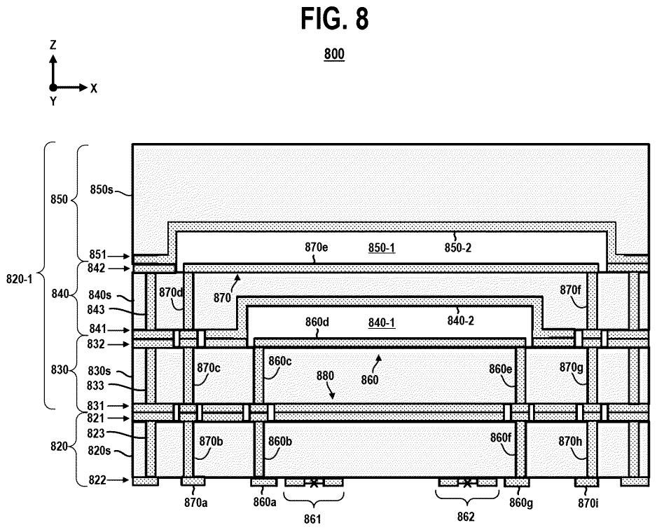

For example, FIG. 8 is a schematic cross-sectional view of a quantum chip package structure which comprises a low-loss multilevel wiring structure with integrated electromagnetic shielding, according to another exemplary embodiment of the disclosure. In particular, FIG. 8 schematically illustrates a quantum chip package structure 800 (or package structure 800) which comprises a quantum chip 820, and a backside multilevel wiring structure 820-1 disposed on a backside of a quantum chip 820. The backside multilevel wiring structure 820-1 comprises a first layer 830 (e.g., first wiring layer), a second layer 840 (e.g., second wiring layer), and a third layer 850 (e.g., upper EMI shielding layer). The package structure 800 further comprises a first qubit coupling bus 860 (or first qubit coupler 860), a plurality of superconducting qubits including a first superconducting qubit 861 and a second superconducting qubit 862 disposed on a frontside of the quantum chip 820, a second qubit coupling bus 870 (or second qubit coupler 870), and a ground shield 880.

As schematically shown in FIG. 8, the first qubit coupler 860 comprises a superconducting transmission line resonator which is routed through the quantum chip 820 and the backside multilevel wiring structure 820-1 to couple the first and second superconducting qubits 861 and 862. The first qubit coupler 860 comprises a plurality of horizontal wire segments and vertical wire segments, e.g., wire segments 860a, 860b, 860c, 860d, 860e, 860f, and 860g. The wire segments 860a, 860d, and 860g comprise horizontal wire segments of the first qubit coupler 860, which comprise patterned metal features of metallization layers, while the wire segments 860b, 860c, 860e, and 860f comprise vertical wire segments of the first qubit coupler 860, which comprise TSVs of the quantum chip 820 and the first layer 830 of the backside multilevel wiring structure 820-1. The second qubit coupler 870 comprises a plurality of horizontal wire segments and vertical wire segments, e.g., wire segments 870a, 870b, 870c, 870d, 870e, 870f, 870g, 870h, and 870i. The wire segments 870a, 870e, and 870i comprise horizontal wire segments of the second qubit coupler 870, which comprise patterned metal features of metallization layers, while the wire segments 870b, 870c, 870d, 870f, 870g, and 870h comprise vertical wire segments of the second qubit coupler 870, which comprise TSVs of the quantum chip 820, the first layer 830, and the second layer 840 of the backside multilevel wiring structure 820-1.

The quantum chip 820 comprises a thinned dielectric substrate 820s, a first metallization layer 821 formed on a first surface of the thinned dielectric substrate 820s, a second metallization layer 822 formed on a second surface of the thinned dielectric substrate 820s, and a plurality TSVs formed in the thinned dielectric substrate 820s, including ground TSVs 823 and signal TSVs (e.g., vertical wire segments 860b, 860f, 870b, and 870h of the first and second qubit couplers 860 and 870). The first metallization layer 821 comprises a ground plane which is a component of the ground shield 880. The second metallization layer 822 comprises a plurality of patterned metal features including, but not limited to, a ground plane, qubit readout resonators, as well as other patterned metal features such as, e.g., qubit capacitor pads of the first and second superconducting qubits 861 and 862, transmission lines, qubit control lines, horizonal wire segments of qubit coupling buses, solder bump pads, etc.

The first layer 830 (or first thinned chip with TSVs) comprises a thinned dielectric substrate 830s (e.g., interlayer dielectric layer), a first metallization layer 831 formed on a first surface of the thinned dielectric substrate 830s, a second metallization layer 832 formed on a second surface of the thinned dielectric substrate 830s, and a plurality of TSVs formed in the thinned dielectric substrate 830s, including ground TSVs 833 (which form a via fence), and signal TSVs (e.g., vertical wire segments 860c, 860e, 870c, and 870g of the first and second qubit couplers 860 and 870). The first metallization layer 831 comprises a ground plane which is a component of the ground shield 880. The quantum chip 820 and the first layer 830 are bonded together via, e.g., metal-to-metal bonding of the first metallization layers 821 and 831 (or portions thereof).

The second metallization layer 832 comprises a plurality of patterned metal features including, but not limited to, a ground plane, and horizontal wiring of one or more qubit coupler buses (e.g., horizontal wire segment 860d of the first qubit coupler 860). Moreover, the plurality ground TSVs 833 serve as ground vias that are disposed in the thinned dielectric substrate 830s. In some embodiments, as noted above, a plurality of the ground TSVs 833 are arranged to form a via fence that surrounds an inner region of the thinned dielectric substrate 830s which comprises the horizontal wire segment 860d and the respective vertical wire segments 860c, 860e, 870c, and 870g of the first and second qubit couplers 860 and 870.

The second layer 840 (or second thinned chip with TSVs) comprises a thinned dielectric substrate 840s (e.g., second interlayer dielectric layer), a first metallization layer 841 formed on a first surface of the thinned dielectric substrate 840s, a second metallization layer 842 formed on a second surface of the thinned dielectric substrate 840s, and a plurality of TSVs formed in the thinned dielectric substrate 840s, including ground TSVs 843 (which form a via fence), and signal TSVs (e.g., vertical wire segments 870d and 870f of the second qubit coupler 870). The first metallization layer 841 comprises a patterned ground plane, and other features, e.g., TSV bond/landing pads.

The second metallization layer 842 comprises a plurality of patterned metal features including, but not limited to, a ground plane, and horizontal wiring of one or more qubit coupler buses (e.g., horizontal wire segment 870e of the second qubit coupler 870). Moreover, the plurality ground TSVs 843 serve as ground vias that are disposed in the thinned dielectric substrate 840s. In some embodiments, as noted above, a plurality of the ground TSVs 843 are arranged to form a via fence that surrounds an inner region of the thinned dielectric substrate 840s which comprises the horizontal wire segment 870e and the vertical wire segments 870d and 870f of the second qubit coupler 870.

Furthermore, as schematically shown in FIG. 8, the second layer 840 comprises a cavity 840-1 (e.g., etched channel) which is formed in the thinned dielectric substrate 840s, and a metallization layer 840-2 which is coated on inner surfaces of the cavity 840-1. The cavity 840-1 is aligned to, and disposed over, the horizontal wire segment 860d of the first qubit coupler 860 (as well as other wiring of qubit couplers that may be disposed on the surface of thinned dielectric substrate 830s of the first layer 830). The metallization layer 840-2 which lines the inner surfaces of the cavity 840-1 is integrated with the ground plane metallization of the first metallization layer 841. The metallization layer 840-2 serves as a ground shield that is configured to provide electromagnetic shielding and isolation between the first qubit coupler 860 and wiring of, e.g. the second qubit coupler 870 of second layer 840 of the multilevel wiring structure 820-1.

The third layer 850 serves as upper EMI shielding layer. The third layer 850 comprises a cavity 850-1 (e.g., etched channel), and a metallization layer 851 which is disposed on a bottom surface of the substrate 850s and which is integrated with the metallization layer 850-2 that is disposed on inner surfaces of the cavity 850-1. The cavity 850-1 is aligned to, and disposed over, the horizontal wire segment 870e of the second qubit coupler 870 (as well as other wiring of qubit couplers that may be disposed on the surface of thinned dielectric substrate 840s of the second layer 840). The metallization layer 850-2 which lines the inner surfaces of the cavity 850-1 is integrally formed with ground plane metallization of the metallization layer 851, to provide an upper ground shield that is configured to provide electromagnetic shielding and isolation for the multilevel wiring structure 820-1. For example, the metallization layers 851 and 850-2 provide an upper ground shield that is configured to electromagnetically shield the second qubit coupler 870 (and other qubit couplers which are routed through the backside multilevel wiring structure 820-1 from the outside environment.

It is to be noted that FIG. 8 illustrates an exemplary embodiment of a package structure in which the cavities 840-1 and 850-1 are configured to provide higher propagation velocity of signals transmitted on, e.g., the first and second qubit couplers 860 and 870, for reasons as discussed above. Furthermore, the metallization layer 840-2 that is disposed on the inner surfaces of the cavity 840-1 of the second layer 840 provides a ground shield which serves to shield the first qubit coupler 860 from the second qubit coupler 870. The exemplary structural configuration eliminates the need to incorporate an additional ground plane layer between the first and second layers 830 and 840. For example, as shown in FIG. 3A, the wiring of the first and second qubit couplers 380 and 385 of the first and third layers 330 and 350 is shielded and isolated from each other by virtue of the intervening second layer 340 (ground plane layer) which is utilized to provide the second ground shield 392. In contrast, in the exemplary embodiment shown in FIG. 8, the metallization 840-2 on the inner surfaces of the cavity 840-1 of the second layer 840 provides a similar shielding function as the second ground shield 392 in FIG. 3A, but without the need for the extra ground plane layer (e.g., without the need of the second layer 340, FIG. 3A).

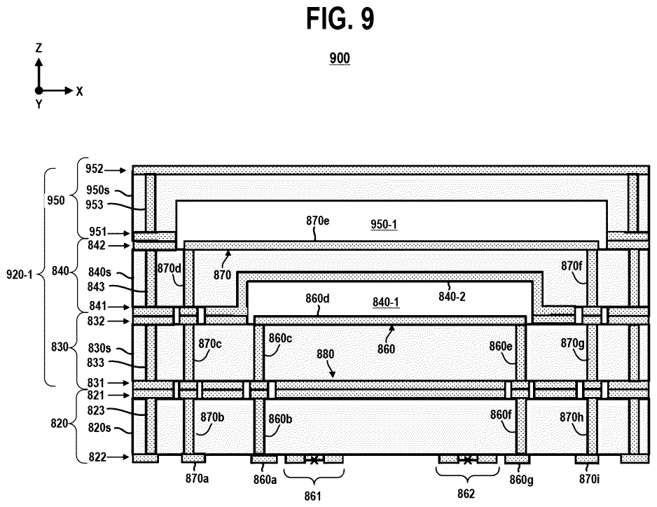

Next, FIG. 9 is a schematic cross-sectional view of a quantum chip package structure which comprises a low-loss multilevel wiring structure with integrated electromagnetic shielding, according to another exemplary embodiment of the disclosure. In particular, FIG. 9 schematically illustrates a quantum chip package structure 900 (or package structure 900) which is similar to the package structure 800 of FIG. 8, except that the package structure 900 comprises an alternative embodiment of a backside multilevel wiring structure 920-1 disposed on a backside of the quantum chip 820. More specifically, the backside multilevel wiring structure 920-1 comprises a different embodiment of a third layer 950 which serves as an upper EMI shielding layer.

As shown in FIG. 9, the third layer 950 comprises a thinned substrate 950s with a cavity 950-1 (e.g., etched channel), a first metallization layer 951 which is disposed on a bottom surface of the thinned substrate 950s, a second metallization layer 952 which is disposed on an upper surface of the thinned substrate 950s, and a plurality of ground TSVs 953 which are arranged to form a via fence, similar to the exemplary embodiment discussed above. In this exemplary embodiment, the cavity 950-1 is aligned to, and disposed over, the horizontal wire segment 870e of the second qubit coupler 870 (as well as other wiring of qubit couplers that may be disposed on the surface of thinned dielectric substrate 840s of the second layer 840), which enables higher propagation velocity of signals transmitted on, e.g., the second qubit coupler 870, for reasons as discussed above.

In the exemplary embodiment of FIG. 9, the cavity 950-1 does not have a metallization layer disposed on the inner surface of the cavity 950-1. Instead, the second metallization layer 952 serves as an upper ground shield that is configured to provide electromagnetic shielding and isolation for the backside multilevel wiring structure 920-1 from the external environment. In particular, the second metallization layer 952 provide an upper ground shield that is configured to electromagnetically shield the second qubit coupler 870 (and other qubit couplers which are routed through the backside multilevel wiring structure 920-1) from the outside environment. The second metallization layer 952 is connected to the underlying ground wiring via the ground TSVs 953 which, as noted above, forms a via fence that surrounds the wiring of the second metallization layer 842 of the second layer 840.

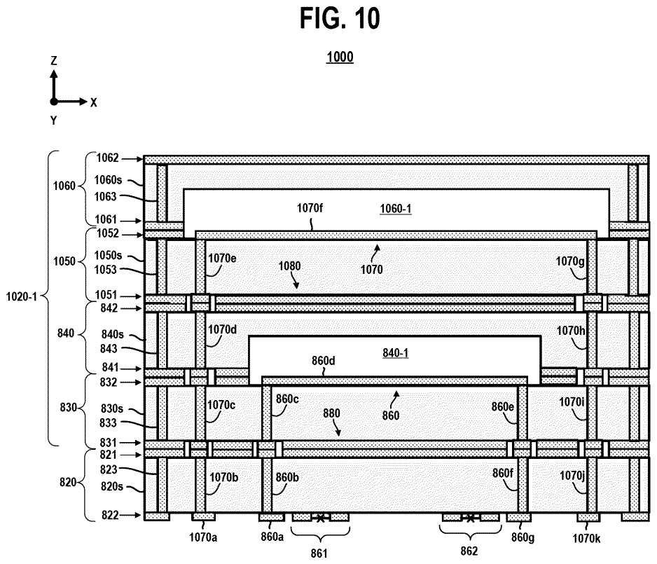

Next, FIG. 10 is a schematic cross-sectional view of a quantum chip package structure which comprises a low-loss multilevel wiring structure with integrated electromagnetic shielding, according to another exemplary embodiment of the disclosure. In particular, FIG. 10 schematically illustrates a quantum chip package structure 1000 (or package structure 1000) which is similar to the package structure 800 of FIG. 8, except that the package structure 1000 comprises an alternative embodiment of a backside multilevel wiring structure 1020-1 disposed on a backside of the quantum chip 820. For example, the backside multilevel wiring structure 1020-1 comprises a different embodiment of the second layer 840 wherein the cavity 840-1 of the thinned dielectric substrate 840s is not lined with metallization layer 840-2 to provide a ground shield. Instead, the second metallization layer 842 of the second layer 840 comprises a ground plane which is a component of a second ground shield 1080 of the package structure 1000, which is configured to isolate and shield the first qubit coupler 860 from wiring in upper layers (e.g., third layer 1050).

The package structure 1000 comprises a third layer 1050 which comprises a wiring layer, and a fourth layer 1060 which serves as an upper EMI shielding layer. The package structure 1000 comprises a second qubit coupler 1070 which comprises a plurality of horizontal wire segments and vertical wire segments, e.g., wire segments 1070a, 1070b, 1070c, 1070d, 1070e, 1070f, 1070g, 1070h, 1070i, 1070j, and 1070k. The wire segments 1070a, 1070f, and 1070k comprise horizontal wire segments of the second qubit coupler 1070, which comprise patterned metal features of metallization layers, while the wire segments 1070b, 1070c, 1070d, 1070e, 1070g, 1070h, 1070i, and 1070k comprise vertical wire segments of the second qubit coupler 1070, which comprise TSVs of the quantum chip 820, the first layer 830, the second layer 840, and the third layer 1050 of the backside multilevel wiring structure 1020-1.

The third layer 1050 (thinned chip with TSVs) comprises a thinned dielectric substrate 1050s (e.g., interlayer dielectric layer), a first metallization layer 1051 formed on a first surface of the thinned dielectric substrate 1050s, a second metallization layer 1052 formed on a second surface of the thinned dielectric substrate 1050s, and a plurality of TSVs formed in the thinned dielectric substrate 1050s, including ground TSVs 1053 (which form a via fence), and signal TSVs (e.g., vertical wire segments 1070e and 1070g of the second qubit coupler 1070). The first metallization layer 1051 comprises a ground plane which is a component of the second ground shield 1080.

The fourth layer 1060 comprises a thinned substrate 1060s with a cavity 1060-1 (e.g., etched channel), a first metallization layer 1061 which is disposed on a bottom surface of the thinned substrate 1060s, a second metallization layer 1062 which is disposed on an upper surface of the thinned substrate 1060s, and a plurality of ground TSVs 1063 which are arranged to form a via fence, similar to the exemplary embodiment discussed above. In this exemplary embodiment, the cavity 1060-1 is aligned to, and disposed over, the horizontal wire segment 1070f of the second qubit coupler 1070 (as well as other wiring of qubit couplers that may be disposed on the surface of thinned dielectric substrate 1050s of the third layer 1050), which enables higher propagation velocity of signals transmitted on, e.g., the second qubit coupler 1070, for reasons as discussed above.

The cavity 1060-1 does not have a metallization layer disposed on the inner surface of the cavity 1060-1. Instead, the second metallization layer 1062 serves as an upper ground shield that is configured to provide electromagnetic shielding and isolation for the backside multilevel wiring structure 1020-1 from the external environment. In particular, the second metallization layer 1062 provides an upper ground shield that is configured to electromagnetically shield the second qubit coupler 1070 (and other qubit couplers which are routed through the backside multilevel wiring structure 1020-1) from the outside environment. The second metallization layer 1062 is connected to the underlying ground wiring via the ground TSVs 1063 which, as noted above, forms a via fence that surrounds the wiring of the second metallization layer 1052 of the third layer 1050.

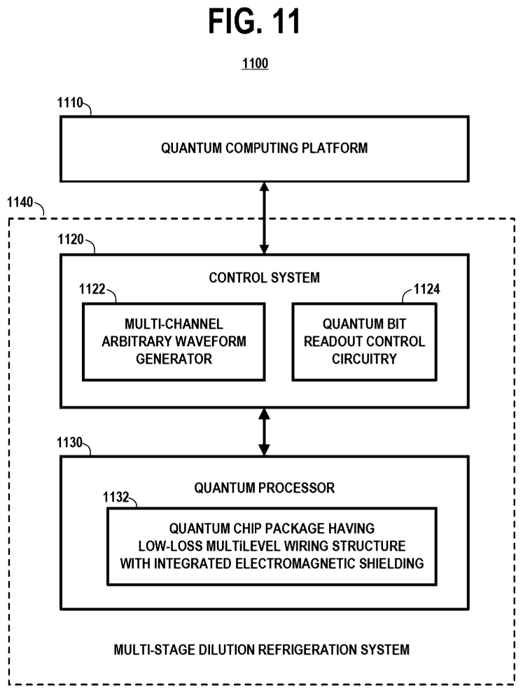

FIG. 11 schematically illustrates a quantum computing system which comprises a quantum processor which comprises a multilevel wiring structure having integrated superconducting qubits, according to an exemplary embodiment of the disclosure. In particular, FIG. 11 schematically illustrates a quantum computing system 1100 which comprises a quantum computing platform 1110, a control system 1120, and a quantum processor 1130. In some embodiments, the control system 1120 comprises a multi-channel arbitrary waveform generator 1122, and quantum bit readout control circuitry 1124. In an exemplary embodiment, the quantum processor 1130 comprises at least one quantum chip package structure 1132 having a low-loss backside multilevel wiring structure with integrated electromagnetic shielding. For example, the quantum chip package structure 1132 can be implemented using any one of the exemplary package structures 100, 200, 300, and 600, 800, 900, 1000, etc., as may be needed for a given application or quantum system configuration.

In some embodiments, the control system 1120 and the quantum processor 1130 are disposed in a dilution refrigeration system 1140 which can generate cryogenic temperatures that are sufficient to operate components of the control system 1120 for quantum computing applications. For example, the quantum processor 1130 may need to be cooled down to near-absolute zero, e.g., 6-15 millikelvin (mK), to allow the superconducting qubits to exhibit quantum behaviors. In some embodiments, the dilution refrigeration system 1140 comprises a multi-stage dilution refrigerator where the components of the control system 1120 can be maintained at different cryogenic temperatures, as needed. For example, while the quantum processor 1130 may need to be cooled down to, e.g., 10-15 mK, the circuit components of the control system 1120 may be operated at cryogenic temperatures greater than 10-15 mK, depending on the configuration of the quantum computing system. In other embodiments, some components of the control system 1120 may comprise electronic components that are disposed and operated in a room temperature environment.

In some embodiments, the multi-channel arbitrary waveform generator (AWG) 1122 and other suitable microwave pulse signal generators are configured to generate the microwave control pulses that are applied to the qubit drive lines, and the coupler drive lines to control the operation of the superconducting qubits and associated qubit coupler circuitry, when performing various gate operations to execute a given certain quantum information processing algorithm. In some embodiments, the multi-channel AWG 1122 comprises a plurality of AWG channels, which control respective superconducting qubits on qubit chips within the quantum chip package structure 1132 of the quantum processor 1130. In some embodiments, each AWG channel comprises a baseband signal generator, a digital-to-analog converter (DAC) stage, a filter stage, a modulation stage, and an impedance matching network, and a phase-locked loop system to generate local oscillator (LO) signals (e.g., quadrature LO signals LO_I and LO_Q) for the respective modulation stages of the respective AWG channels.

In some embodiments, the multi-channel AWG 1122 comprises a quadrature AWG system which is configured to process quadrature signals, wherein a quadrature signal comprises an in-phase (I) signal component, and a quadrature-phase (Q) signal component. In each AWG channel the baseband signal generator is configured to receive baseband data as input (e.g., from the quantum computing platform), and generate digital quadrature signals I and Q which represent the input baseband data. In this process, the baseband data that is input to the baseband signal generator for a given AWG channel is separated into two orthogonal digital components including an in-phase (I) baseband component and a quadrature-phase (Q) baseband component. The baseband signal generator for the given AWG channel will generate the requisite digital quadrature baseband IQ signals which are needed to generate an analog waveform (e.g., sinusoidal voltage waveform) with a target center frequency that is configured to operate or otherwise control a given quantum bit that is coupled to the output of the given AWG channel.

The DAC stage for the given AWG channel is configured to convert a digital baseband signal (e.g., a digital IQ signal output from the baseband signal generator) to an analog baseband signal (e.g., analog baseband signals I(t) and Q(t)) having a baseband frequency. The filter stage for the given AWG channel is configured to the filter the IQ analog signal components output from the DAC stage to thereby generate filtered analog IQ signals. The modulation stage for the given AWG channel is configured to perform analog IQ signal modulation (e.g., single-sideband (SSB) modulation) by mixing the filtered analog signals I(t) and Q(t), which are output from the filter stage, with quadrature LO signals (e.g., an in-phase LO signal (LO_I) and a quadrature-phase LO signal (LO_Q)) to generate and output an analog RF signal (e.g., a single-sideband modulated RF output signal).

In some embodiments, the quantum bit readout control circuitry 1124 comprises a microwave pulse signal generator that is configured to applying a microwave tone to a given readout resonator line of a given superconducting qubit to perform a readout operation to readout the state of the given superconducting qubit, as well as circuitry that is configured to process the readout signal generated by the readout resonator line to determine the state of the given superconducting qubit, using techniques known to those of ordinary skill in the art. For example, in some embodiments, a qubit readout line for a given qubit comprise a coplanar waveguide resonator that is configured to have a resonant frequency that is detuned from a transition frequency of the given qubit to enable a dispersive readout operation for reading the quantum state of a given qubit which is coupled to a given readout resonator. A dispersive readout operation involves applying an RF readout control signal (RF_RO) to the given readout resonator, and detecting/processing the readout signal that is reflected out from the given readout resonator. An RF readout control signal that is applied to the given readout resonator has a single frequency tone that is the same or similar to the resonant frequency of the readout resonator, a pulse envelope with a given pulse shape (e.g., gaussian pulse envelope), and given pulse duration. In the dispersive regime of qubit-resonator coupling, the RF readout control signal interacts with the given qubit/resonator system, and the resulting output readout signal which is reflected out from the given readout resonator comprises information (e.g., phase and/or amplitude) that is qubit-state dependent. The quantum bit readout control circuitry 1124 can include various components in qubit readout signal chains including, e.g., microwave isolators, quantum-limited amplifiers (e.g., Josephson junction traveling wave parametric amplifiers), filters, other amplifiers such as high-electron-mobility-transistor (HEMT) amplifiers, etc., which are disposed in stages of the dilution refrigeration system, as well as I/Q mixers, and analog-to-digital converter (ADC) circuitry, which outputs digital readout signals to a hardware or software based discriminators to determine the readout quantum state of superconducting qubits.

The quantum computing platform 1110 comprises a software and hardware platform which comprises various software layers that are configured to perform various functions, including, but not limited to, generating and implementing various quantum applications using suitable quantum programming languages, configuring and implementing various quantum gate operations, compiling quantum programs into a quantum assembly language, implementing and utilizing a suitable quantum instruction set architecture (ISA), etc. In addition, the quantum computing platform 1110 comprises a hardware architecture of processors, memory, etc., which is configured to control the execution of quantum applications, and interface with the control system 1120 to (i) generate digital control signals that are converted to analog microwave control signals by the control system 1120, to control operations of the quantum processor 1130 when executing a given quantum application, and (ii) to obtain and process digital signals received from the control system 1120, which represent the processing results generated by the quantum processor 1130 when executing various gate operations for a given quantum application.

In some exemplary embodiments, the quantum computing platform 1110 of the quantum computing system 1100 may be implemented using any suitable computing system architecture which is configured to implement methods to support quantum computing operations by executing computer readable program instructions that are embodied on a computer program product which includes a computer readable storage medium (or media) having such computer readable program instructions thereon for causing a processor to perform control methods as discussed herein.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and to enable others of ordinary skill in the art to understand the embodiments disclosed herein.

What is claimed is:

1. A package structure, comprising:
superconducting quantum circuit components disposed on a first surface of a first dielectric substrate; and
a multilevel wiring structure disposed on a second surface of the first dielectric substrate, opposite the first surface, wherein the multilevel wiring structure comprises:
wiring to provide connections between at least some of the superconducting quantum circuit components; and
an integrated electromagnetic shielding structure which is configured to shield the wiring of the multilevel wiring structure from electromagnetic interference and to shield the superconducting quantum circuit components from the wiring of the multilevel wiring structure.

2. The package structure of claim 1, wherein:
the superconducting quantum circuit components comprise a first quantum bit and a second quantum bit; and
the wiring of the multilevel wiring structure comprises at least one coupling bus which is routed through the multilevel wiring structure to couple the first quantum bit and the second quantum bit.

3. The package structure of claim 1, wherein:
the integrated electromagnetic shielding structure comprises a first ground shield, a second ground shield, and a plurality of ground vias which are coupled to and between the first ground shield and the second ground shield, and which are arranged to form a via fence between the first and second ground shields;
the wiring of the multilevel wiring structure is disposed between the first ground shield and the second ground shield, and surrounded by the via fence; and
the first ground shield is disposed between the wiring and the superconducting quantum circuit components on the first surface of the first dielectric substrate.

4. The package structure of claim 1, wherein:
the multilevel wiring structure comprises a second dielectric substrate comprising a first metallization layer disposed on a first surface of the second dielectric substrate and a second metallization layer disposed on a second surface of the second dielectric substrate, opposite the first surface thereof;
the first metallization layer comprises a patterned ground plane which is bonded to patterned ground plane disposed on the second surface of the first dielectric substrate; and
the second metallization layer comprises at least one planar transmission line which comprises a horizontal wire segment of the wiring;
through-substrate vias disposed in the second dielectric substrate, which comprises vertical wire segments of the wiring.

5. The package structure of claim 4, wherein the first dielectric substrate and the second dielectric substrate are each formed of monocrystalline dielectric material.

6. The package structure of claim 5, wherein the monocrystalline dielectric material comprises one of a monocrystalline semiconductor material and a monocrystalline oxide material.

7. The package structure of claim 4, wherein the multilevel wiring structure further comprises a cap structure disposed on the second surface of the second dielectric substrate and comprising an inner cavity aligned to, and covering the at least one planar transmission line of the second metallization layer, wherein the cap structure comprises at least one layer of metallic material coated on surfaces of the inner cavity of the cap structure to provide a ground shield component of the integrated electromagnetic shielding structure of the multilevel wiring structure.

8. The package structure of claim 7, wherein the at least one layer of metallic material of the cap structure is bonded to a patterned ground plane of the second metallization layer on the second surface of the second dielectric substrate.

9. The package structure of claim 4, wherein:
the multilevel wiring structure further comprises a third dielectric substrate comprising third metallization layer disposed on a first surface of the third dielectric substrate, and a fourth metallization layer disposed on a second surface of the third dielectric substrate, opposite the first surface thereof;
the third metallization layer comprises a patterned ground plane which is bonded to a patterned ground plane of the second metallization layer of the first dielectric substrate;
the fourth metallization layer comprises a ground plane which comprises a ground shield of the integrated electromagnetic shielding structure of the multilevel wiring structure; and
a plurality of ground vias which are coupled to and between the ground plane of the third metallization layer and the ground plane of the fourth metallization layer, and which are arranged to form a via fence of the integrated electromagnetic shielding structure.

10. A package structure, comprising:
superconducting quantum circuit components disposed on a first surface of a first dielectric substrate; and
a multilevel wiring structure disposed on a second surface of the first dielectric substrate, opposite the first surface, wherein the multilevel wiring structure comprises:
a first layer and a second layer, which comprise wiring that is routed through the multilevel wiring structure to provide connections between at least some of the superconducting quantum circuit components; and
an integrated electromagnetic shielding structure which is configured to shield the wiring of the multilevel wiring structure from electromagnetic interference, to shield the superconducting quantum circuit components from the wiring of the multilevel wiring structure, and to shield the wiring of the first layer from the wiring of the second layer.

11. The package structure of claim 10, wherein:
the superconducting quantum circuit components comprise a plurality of quantum bits;
the first layer comprises at least a first coupling bus which is routed through the multilevel wiring structure to couple a first quantum bit and a second quantum bit; and
the second layer comprises at least a second coupling bus which is routed through the multilevel wiring structure to couple a third quantum bit and a fourth quantum bit.

12. The package structure of claim 10, wherein:
the integrated electromagnetic shielding structure comprises a first ground shield, a second ground shield, a third ground shield, a plurality of ground vias which are coupled to and between the first ground shield and the second ground shield, and which are arranged to form a first via fence between the first and second ground shields, and a plurality of ground vias which are coupled to and between the second ground shield and the second ground shield, and which are arranged to form a second via fence between the second and third ground shields;
the first ground shield is disposed between the wiring of the first layer and the superconducting quantum circuit components on the first surface of the first dielectric substrate.

13. The package structure of claim 10, wherein:
the first layer comprises a second dielectric substrate;
the second layer comprises a third dielectric substrate; and
the first dielectric substrate, the second dielectric substrate, and the third dielectric substrate are each formed of a monocrystalline dielectric material.

14. A package structure, comprising:
a first dielectric substrate comprising superconducting quantum circuit components disposed on a first surface of the first dielectric substrate, and a first metallization layer disposed on a second surface of the first dielectric substrate and comprising a first ground plane;
a second dielectric substrate comprising a second metallization layer and a third metallization layer, wherein the second metallization layer is disposed on a first surface of the second dielectric substrate and comprises a second ground plane that is bonded to the first ground plane, and wherein the third metallization layer is disposed on a second surface of the second dielectric substrate, and comprises a third ground plane and wiring to provide connections between at least some of the superconducting quantum circuit components;
a third dielectric substrate comprising a fourth metallization layer and a fifth metallization layer, wherein the fourth metallization layer is disposed on a first surface of the third dielectric substrate, and comprises a fourth ground plane which is bonded to the third ground plane, and wherein the fifth metallization layer is disposed on a second surface of the third dielectric substrate and comprises a fifth ground plane; and
an electromagnetic shielding structure configured to shield the wiring of the third metallization layer from the superconducting quantum circuit components, wherein the electromagnetic shielding structure comprises a first ground shield which comprises the bonded first and second ground planes, and a second ground shield which comprises the fifth ground plane.

15. The package structure of claim 14, wherein the first dielectric substrate, the second dielectric substrate, and the third dielectric substrate are each formed of a monocrystalline dielectric material.

16. The package structure of claim 14, wherein:
the electromagnetic shielding structure comprises a via fence; and
the via fence comprises a plurality of ground through-substrate vias, which are disposed in the second dielectric substrate and the third dielectric substrate, and which surround the wiring of the third metallization layer.

17. The package structure of claim 14, further comprising:
a fourth dielectric substrate comprising sixth metallization layer and a seventh metallization layer, wherein the sixth metallization layer is disposed on a first surface of the fourth dielectric substrate, and comprises a sixth ground plane which is bonded to the fifth ground plane, and wherein the seventh metallization layer is disposed on a second surface of the fourth dielectric substrate and comprises a seventh ground plane, and wiring to provide connections between at least some of the superconducting quantum circuit components; and
a fifth dielectric substrate comprising an eighth metallization layer and a ninth metallization layer, wherein the eighth metallization layer is disposed on a first surface of the fifth dielectric substrate, and comprises an eighth ground plane which is bonded to the seventh ground plane, and wherein the ninth metallization layer is disposed on a second surface of the fifth dielectric substrate and comprises a nineth ground plane; and
wherein the second ground shield of the electromagnetic shielding structure comprises the bonded fifth ground plane and sixth ground plane; and
wherein the electromagnetic shielding structure comprises a third ground shield which comprises the nineth ground plane.

18. The package structure of claim 17, wherein:
the electromagnetic shielding structure comprises a via fence; and
the via fence comprises a plurality of ground through-substrate vias, which are disposed in the second dielectric substrate, the third dielectric substrate, the fourth dielectric substrate, and the fifth dielectric substrate, and which surround the wiring of the third metallization layer and the wiring of the fifth metallization layer.

19. A package structure, comprising:
a quantum chip comprising a dielectric substrate, a plurality of superconducting quantum bits and quantum circuit components disposed on a frontside of the dielectric substrate, and a ground plane disposed on a backside of the dielectric substrate; and
a multilevel wiring structure disposed on the backside of the dielectric substrate of the quantum chip and comprising at least one coupling bus which is routed through the multilevel wiring structure and the dielectric substrate of the quantum chip to couple a first superconducting quantum bit and a second superconducting quantum bit of the plurality of superconducting quantum bits, wherein the multilevel wiring structure comprises:
a plurality of layers, each layer comprising a dielectric substrate formed of a monocrystalline dielectric material, metallization layers disposed on first and second surfaces of the dielectric substrate, and through-substrate vias disposed in the dielectric substrate; and
an integrated electromagnetic shielding structure which comprises patterned features of the metallization layers and at least a portion of the through-substrate vias of one or more layers of the plurality of layers, wherein the integrated electromagnetic shielding structure is configured to shield the at least one coupling bus in the multilevel wiring structure from electromagnetic interference, and to shield the superconducting quantum bits and the quantum circuit components from the at least one coupling bus in the multilevel wiring structure.

20. The package structure of claim 19, wherein:
the integrated electromagnetic shielding structure comprises a first ground shield, a second ground shield, and a plurality of ground vias which are coupled to and between the first ground shield and the second ground shield, and which are arranged to form a via fence between the first and second ground shields; and
a portion of the at least one coupling bus of the multilevel wiring structure is disposed between the first ground shield and the second ground shield, and surrounded by the via fence.

21. The package structure of claim 20, wherein:
the multilevel wiring structure comprises a cap structure which is bonded to an uppermost layer of the multilevel wiring structure;
the cap structure comprises an inner cavity aligned to, and covering at least one signal wire of a metallization layer of the uppermost layer of the multilevel wiring structure;
the cap structure comprises at least one layer of metallic material coated on surfaces of the inner cavity of the cap structure to provide an upmost ground shield component of the integrated electromagnetic shielding structure of the multilevel wiring structure.

22. A method, comprising:
forming first vias and a first metallization layer on a first side of a first dielectric substrate comprising a monocrystalline dielectric material;
forming second vias and a second metallization layer on a first side of a second dielectric substrate comprising a monocrystalline dielectric material;
bonding the first dielectric substrate and the second dielectric substrate by metal-to-metal bonding the first metallization layer and the second metallization layer;
forming a thinned second dielectric substrate by thinning down a second side of the second dielectric substrate to reveal the second vias;
forming a third metallization layer on the thinned second dielectric substrate in contact with the revealed second vias, the third metallization layer comprising a ground plane and at least one planar wire;
forming a thinned first dielectric substrate by thinning down a second side the first dielectric substrate to reveal the first vias; and
forming a fourth metallization layer and a plurality of superconducting quantum bits on the thinned first dielectric substrate, with the fourth metallization layer in contact with the revealed first vias.

23. The method of claim 22, wherein:
the thinned second dielectric substrate comprises an interlayer dielectric layer of a multilevel wiring structure;
the at least one planar wire, and a plurality of vias of the first vias and the second vias collectively comprise a coupling bus which a first superconducting quantum bit and a second superconducting bit of the plurality of superconducting quantum bits.

24. The method of claim 22, further comprising:
forming third vias and a fifth metallization layer on a first side of a third dielectric substrate comprising a monocrystalline dielectric material; and
prior to forming the thinned first dielectric substrate, the method comprising:
bonding the third dielectric substrate and the thinned second dielectric substrate by metal-to-metal bonding the third metallization layer of the thinned second dielectric substrate and the fifth metallization layer of the third dielectric substrate;
forming a thinned third dielectric substrate by thinning down a second side of the third dielectric substrate to reveal the third vias; and
forming a sixth metallization layer on the thinned third dielectric substrate in contact with the revealed third vias, the sixth metallization layer comprising a ground plane.

25. The method of claim 24, wherein:
the bonded first metallization layer and second metallization layer comprise a first ground shield;
the ground plane of the sixth metallization layer comprises a second ground shield;
the at least one planar wire of the third metallization layer is disposed between the first and second ground shields; and
at least a portion of the second vias and the third vias comprise ground vias that are arranged to form a via fence which is connected to and between the first and second ground shields, and which surrounds the at least one planar wire of the third metallization layer.
